(19) United States
(12) Patent Application Publication
(10) Pub. No.: US 2025/0287612 A1
(43) Pub. Date: Sep. 11, 2025

(54) SEMICONDUCTOR DEVICE

(71) Applicant: Semiconductor Energy Laboratory Co., Ltd., Atsugi-shi, Kanagawa-ken (JP)

(72) Inventors: Yuto YAKUBO, Atsugi (JP); Yoshiyuki KUROKAWA, Sagamihara (JP); Hiromichi GODO, Isehara (JP); Satoru OHSHITA, Hadano (JP)

(21) Appl. No.: 18/862,984

(22) PCT Filed: May 1, 2023
(86) PCT No.: PCT/IB2023/054508

§ 371 Date: Nov. 5, 2024

(30) Foreign Application Priority Data
May 16, 2022 (JP) 2022-079907

(51) Int. Cl. H10B 80/00; G11C 11/405; G11C 11/4074; H01L 25/065; H01L 25/18; H10B 12/00

(52) U.S. Cl. CPC H10B 80/00; G11C 11/405; G11C 11/4074; H01L 25/0657; H01L 25/18; H10B 12/00; H01L 2225/06513; H01L 2225/06541; H01L 2225/06589

(57) ABSTRACT

A semiconductor device with a novel structure is provided. A base die including a first power supply circuit that generates a first voltage, a first die including a second power supply circuit that generates a second voltage by being supplied with the first voltage, and a second die including a functional circuit that operates by being supplied with the second voltage are included in the semiconductor device. The first die and the second die each include a first through electrode and a second through electrode. The first die is provided over the base die. The second die is provided in contact with an upper layer or a lower layer of the first die. The base die and the first die are electrically connected via the first through electrode. The first die and the second die are electrically connected via the second through electrode.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting device, a power storage device, a storage device, a method for driving any of them, and a method for manufacturing any of them.

### BACKGROUND ART

In recent years, research and development have been actively conducted on a structure in which a plurality of dies (e.g., silicon dies) provided with circuits having different functions, such as an SRAM cell and a DRAM cell, are three-dimensionally provided to be stacked (e.g., Non-Patent Document 1 and Non-Patent Document 2).

In a plurality dies that are stacked, a wiring load is reduced by a technique using a through electrode such as a TSV (Through Silicon Via), a Cu-to-Cu (copper-to-copper) direct bonding technique, or the like, whereby reduction in power consumption and an increase in speed (low latency) are achieved. In a semiconductor device formed by stacking dies including different functional circuits, clock signal management and power management in the Z direction (the direction in which the dies are stacked) are important.

### REFERENCE

### Non-Patent Document

[Non-Patent Document 1] W. Gomes et al., ISSCC Dig. Tech. Papers, pp. 42-43, 2022.

[Non-Patent Document 2] M. Park et al., ISSCC Dig. Tech. Papers, pp. 444-445, 2022.

### SUMMARY OF THE INVENTION

### Problems to be Solved by the Invention

When a power supply circuit is provided in a base die (a die over which a plurality of dies are provided to be stacked), a voltage drop has a greater influence in a structure in which power supply voltage is supplied to a die in an upper layer away from the base die. Thus, the uniformity of voltage supplied from the power supply circuit might not be maintained in power management in the Z direction.

An object of one embodiment of the present invention is to provide a semiconductor device with a novel structure having excellent uniformity of voltage supplied to functional circuits included in a plurality of dies in a structure in which the plurality of dies are three-dimensionally stacked over a base die. Another object of one embodiment of the present invention is to provide a semiconductor device with a novel structure in which power consumption of a power supply circuit is reduced in a structure in which a plurality of dies are three-dimensionally stacked over a base die. Another object of one embodiment of the present invention is to provide a semiconductor device with a novel structure in which influence of heat generation in a power supply circuit can be reduced in a structure in which a plurality of dies are three-dimensionally stacked over a base die. Another object of one embodiment of the present invention is to provide a semiconductor device with a novel structure.

Note that the objects of one embodiment of the present invention are not limited to the objects listed above. The objects listed above do not preclude the existence of other objects.

The other objects are objects that are not described in this section and are described below. The objects that are not described in this section are derived from the description of the specification, the drawings, and the like and can be extracted as appropriate from the description by those skilled in the art. One embodiment of the present invention solves at least one of the above objects and the other objects.

### Means for Solving the Problems

One embodiment of the present invention is a semiconductor device including a base die including a first power supply circuit that generates a first voltage, a first die including a second power supply circuit that generates a second voltage by being supplied with the first voltage, and a second die including a functional circuit that operates by being supplied with the second voltage. The first die and the second die each include a first through electrode and a second through electrode; the first die is provided over the base die; the second die is provided in contact with an upper layer or a lower layer of the first die; the base die and the first die are electrically connected via the first through electrode; and the first die and the second die are electrically connected via the second through electrode.

In the semiconductor device of one embodiment of the present invention, the first power supply circuit is preferably a switching regulator.

In the semiconductor device of one embodiment of the present invention, the second power supply circuit is preferably a series regulator.

In the semiconductor device of one embodiment of the present invention, the functional circuit is preferably a circuit having one or more of functions of an arithmetic circuit, a peripheral circuit, a memory circuit, and a driver circuit.

In the semiconductor device of one embodiment of the present invention, a heat radiation layer is preferably included and the heat radiation layer is preferably provided between the first die and the second die.

In the semiconductor device of one embodiment of the present invention, the first through electrodes and the second through electrodes that are provided in different dies are preferably electrically connected via a metal bump.

In the semiconductor device of one embodiment of the present invention, the second die preferably has a layer including a transistor in which a channel formation region thereof includes an oxide semiconductor, and the layer including the transistor is preferably provided to be stacked.

In the semiconductor device of one embodiment of the present invention, the oxide semiconductor preferably includes In, Ga, and Zn.

One embodiment of the present invention is a semiconductor device including a base die including a first power supply circuit that generates a first voltage, a first die including a second power supply circuit that generates a second voltage by being supplied with the first voltage, and a second die and a third die each including a functional circuit that operates by being supplied with the second voltage; the first die, the second die, and the third die each include a through electrode; the first die is provided over the base die; the second die is provided in contact with a lower layer of the first die; the third die is provided in contact with an upper layer of the first die; the base die and the first die are electrically connected via the first through electrode; and the first die, the second die, and the third die are electrically connected via the second through electrode.

In the semiconductor device of one embodiment of the present invention, the first power supply circuit is preferably a switching regulator.

In the semiconductor device of one embodiment of the present invention, the second power supply circuit is preferably a series regulator.

In the semiconductor device of one embodiment of the present invention, the functional circuit is preferably a circuit having one or more of functions of an arithmetic circuit, a peripheral circuit, a memory circuit, and a driver circuit.

In the semiconductor device of one embodiment of the present invention, a heat radiation layer is preferably provided, and the heat radiation layer is preferably provided between the first die and the second die and between the first die and the third die.

In the semiconductor device of one embodiment of the present invention, the first through electrode and the second through electrode that are provided in different dies are preferably electrically connected via a metal bump.

In the semiconductor device of one embodiment of the present invention, the second die and the third die each preferably have a layer including a transistor in which a channel formation region thereof includes an oxide semiconductor, and the layer including the transistor is preferably provided to be stacked.

In the semiconductor device of one embodiment of the present invention, the oxide semiconductor preferably includes In, Ga, and Zn.

Note that other embodiments of the present invention will be described in the following embodiments with reference to the drawings.

### Effect of the Invention

One embodiment of the present invention can provide a semiconductor device with a novel structure having excellent uniformity of voltage supplied to functional circuits included in a plurality of dies in a structure in which the plurality of dies are three-dimensionally stacked over a base die. Another embodiment of the present invention can provide a semiconductor device with a novel structure in which power consumption of a power supply circuit is reduced in a structure in which a plurality of dies are three-dimensionally stacked over a base die. Another embodiment of the present invention can provide a semiconductor device with a novel structure in which influence of heat generation in a power supply circuit can be reduced in a structure in which a plurality of dies are three-dimensionally stacked over a base die. Another embodiment of the present invention can provide a semiconductor device with a novel structure.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

FIG. 1A and FIG. 1B are diagrams each illustrating a structure example of a semiconductor device.

FIG. 2A and FIG. 2B are diagrams each illustrating a structure example of a semiconductor device.

FIG. 3A and FIG. 3B are diagrams each illustrating a structure example of a semiconductor device.

FIG. 4A and FIG. 4B are diagrams each illustrating a structure example of a semiconductor device.

FIG. 5A and FIG. 5B are diagrams each illustrating a structure example of a semiconductor device.

FIG. 6A and FIG. 6B are diagrams each illustrating a structure example of a semiconductor device.

FIG. 7A, FIG. 7B, and FIG. 7C are diagrams each illustrating a structure example of a semiconductor device.

FIG. 8A and FIG. 8B are diagrams each illustrating a structure example of a semiconductor device.

FIG. 9A to FIG. 9D are diagrams each illustrating a structure example of a semiconductor device.

FIG. 10 is a diagram illustrating a structure example of a semiconductor device.

FIG. 11A to FIG. 11C are diagrams each illustrating a structure example of a semiconductor device.

FIG. 12 is a diagram illustrating a structure example of a memory portion.

FIG. 13A is a diagram illustrating a structure example of a memory layer. FIG. 13B is a diagram illustrating an equivalent circuit in the memory layer.

FIG. 14 is a diagram illustrating a structure example of a memory portion.

FIG. 15A is a diagram illustrating a structure example of a memory layer. FIG. 15B is a diagram illustrating an equivalent circuit in the memory layer.

FIG. 16A and FIG. 16B are diagrams each illustrating an example of an electronic component.

FIG. 17A and FIG. 17B are diagrams each illustrating an example of an electronic device, and

FIG. 17C to FIG. 17E are diagrams each illustrating an example of a large computer.

FIG. 18 is a diagram illustrating an example of a device for space.

FIG. 19 is a diagram illustrating an example of a storage system that can be used in a data center.

### MODE FOR CARRYING OUT THE INVENTION

Embodiments will be described below with reference to the drawings. The embodiments can be implemented with various modes. It will be readily appreciated by those skilled in the art that modes and details can be changed in various ways without departing from the spirit and scope of the present invention. Therefore, the present invention should not be construed as being limited to the description of embodiments below.

In the drawings, the size, the layer thickness, or the region is sometimes exaggerated for clarity. Therefore, the size, the layer thickness, or the region is not limited to the illustrated scale. Note that the drawings schematically show ideal examples, and the embodiment of the present invention is not limited to shapes or values shown in the drawings.

Unless otherwise specified, an off-state current in this specification and the like refers to a drain current of a transistor in an off state (also referred to as a non-conduction state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, a metal oxide means an oxide of metal in a broad sense. Metal oxides are classified into an oxide insulator, an oxide conductor (including a transparent oxide conductor), an oxide semiconductor (also simply referred to as OS), and the like. For example, a metal oxide used in an active layer of a transistor is referred to as an oxide semiconductor in some cases. That is, an OS transistor can also be referred to as a transistor including a metal oxide or an oxide semiconductor.

### Embodiment 1

In this embodiment, structure examples of a semiconductor device will be described. A semiconductor device described in one embodiment of the present invention has a function of an SoC (System on a Chip) including a plurality of functional circuits such as a memory circuit and a peripheral circuit in addition to a logic circuit.

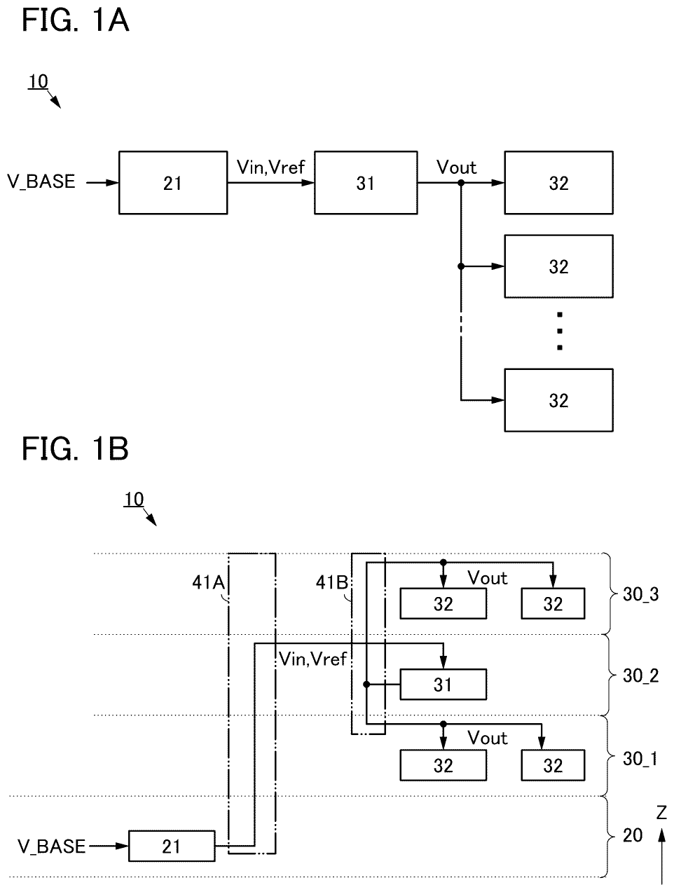

FIG. 1A is a block diagram illustrating the semiconductor device of one embodiment of the present invention. FIG. 1B is a schematic diagram illustrating the semiconductor device of one embodiment of the present invention.

A semiconductor device 10 illustrated in FIG. 1A includes a power supply circuit 21, a power supply circuit 31, and a plurality of functional circuits 32. The power supply circuit 21, the power supply circuit 31, and the plurality of functional circuits 32 included in the semiconductor device 10 illustrated in FIG. 1A are provided in stacked dies. In the schematic diagram illustrated in FIG. 1B, a plurality of dies (e.g., 30_1 to 30_3) are provided over a die (hereinafter, a base die 20). The Z direction in FIG. 1B represents a direction perpendicular to a surface of the base die 20 or a direction in which the dies 30_1 to 30_3 are provided to be stacked over the base die 20.

In the structure of FIG. 1B, the dies stacked over the base die 20 are denoted by 30_1 to 30_3. As for the dies provided to be stacked over the base die 20, a die of an n-th layer can be referred to as a die 30_n, for example. Note that in this embodiment and the like, “die 30” is merely stated in some cases to describe matters related to all of the n layers of the dies formed of the dies 30_1 to 30_n or to show matters common to the layers of the die 30.

The power supply circuit 21 is a circuit that generates a constant voltage Vin and a reference voltage Vref on the basis of a base voltage V_BASE. The power supply circuit 21 is provided in the base die 20. The power supply circuit 21 is preferably a switching regulator, for example. The switching regulator can efficiently generate the constant voltage Vin and the reference voltage Vref on the basis of the base voltage V_BASE. The switching regulator requires a large electronic component such as an inductor and a capacitor. A large electronic component such as an external inductor and a diode can be placed in the base die 20 because it has a larger area than each of the dies 30_1 to 30_3. Note that the constant voltage Vin and the reference voltage Vref are each referred to as a first voltage in some cases. The power supply circuit 21 is referred to as a first power supply circuit in some cases.

Note that the base die 20 provided with the power supply circuit 21 may include a clock generation circuit, an arithmetic circuit such as a CPU core, or a functional circuit such as a memory circuit, other than the power supply circuit 21.

The power supply circuit 31 generates a constant voltage Vout on the basis of the constant voltage Vin and the reference voltage Vref. A plurality of power supply circuits 31 may be provided so as to generate a plurality of different constant voltages Vout. The power supply circuit 31 is preferably a series regulator such as a Low-Drop-Out regulator (LDO Regulator). The series regulator can be formed using an amplifier circuit and an transistor for controlling an output voltage, and thus can be used for a power supply circuit included in the dies 30_1 to 30_3 stacked over the base die 20 without using electronic components such as an inductor and a diode. Note that the constant voltage Vout is referred to as a second voltage in some cases. The power supply circuit 31 is referred to as a second power supply circuit in some cases. The die 30_2 provided with the power supply circuit 31 is referred to as a first die in some cases.

In the structure in which the plurality of dies (e.g., 30_1 to 30_3) are three-dimensionally stacked over the base die 20, the constant voltage Vout can be supplied from the power supply circuit 31 included in the die 30_2 away from the base die 20 to the functional circuits 32 included in the dies 30_1 and 30_3 adjacent to the die 30_2 by providing the die 30_2 including the power supply circuit 31. Thus, the influence of a voltage drop of voltage supplied to the functional circuit 32 can be reduced. Therefore, uniformity of voltage supplied from the power supply circuit can be easily ensured in power management in the Z direction.

The base die 20 and the dies 30_1 to 30_3 include transistors (Si transistors) in which semiconductor layers having channel formation regions include silicon. With the Si transistors, the power supply circuit and the functional circuit can be each formed with a CMOS circuit (a Si CMOS circuit). With this structure, the power supply circuit and the functional circuit formed with the Si CMOS circuit can be provided in each layer. Since the power supply circuit and the functional circuit can be each formed with the CMOS circuit, high-speed operation is possible.

For the semiconductor layer with a channel formation region of the Si transistor, a single crystal semiconductor, a polycrystalline semiconductor, a microcrystalline semiconductor, an amorphous semiconductor, or the like can be used alone or in combination. A semiconductor material is not limited to silicon and can be germanium or the like, for example. Alternatively, a compound semiconductor such as silicon germanium, silicon carbide, gallium arsenide, a nitride semiconductor, or the like can be used.

Note that substrates, which are the base die 20 and the dies 30_1 to 30_3 including Si transistors, can be connected by a technique using a through electrode such as a TSV (Through Silicon Via), a Cu-to-Cu (copper-to-copper) direct bonding technique (a technique for achieving electrical conduction by connecting Cu (copper) pads), or the like to be a stacked element layer. Note that the dies including the through electrodes can be connected via a metal bump (referred to as a micro-bump in some cases).

The constant voltage Vin and the reference voltage Vref are supplied from the power supply circuit 21 included in the base die 20 to the power supply circuit 31 included in the die 30_2 via through electrodes 41A provided in the plurality of dies (e.g., 30_1 to 30_3) over the base die 20. The constant voltage Vout is supplied from the power supply circuit 31 included in the die 30 to the functional circuits 32 included in the dies 30_1 and 30_3 via through electrodes 41B provided in the plurality of dies (e.g., 30_1 to 30_3) over the base die 20. With such a structure, the constant voltage Vin and the reference voltage Vref can be supplied to the die away from the base die, and the power supply circuit 31 that supplies the constant voltage Vout and the functional circuit 32 that is supplied with the constant voltage Vout can be provided close to each other.

The functional circuit 32 is a circuit that functions by being supplied with the constant voltage Vout. The functional circuit 32 is preferably a circuit that has one or more of functions of the arithmetic circuit, the peripheral circuit, the memory circuit, and a driver circuit. When synchronization circuits such as the arithmetic circuit, the peripheral circuit, the memory circuit, or the driver circuit are provided in the dies 30_1 to 30_3 that are stacked over the base die 20, a plurality of synchronization circuits can be placed close to each other, which facilitates timing adjustment of the clock signal and reduces power consumption required for distributing the clock signal. Furthermore, a plurality of functional circuits can be arranged per unit area, so that the semiconductor device can have high functionality. Note that the die 30_1 or the die 30_3 provided with the functional circuit 32 is referred to as the first die in some cases.

The dies 30_1 and 30_3 each including the functional circuit 32 to which the constant voltage Vout is supplied are preferably provided in contact with an upper layer or a lower layer of the die 30_2 including the power supply circuit 31. With this structure, the functional circuit 32 to which the constant voltage Vout is supplied can be placed at an equal distance from the power supply circuit 31.

The arithmetic circuit is a functional circuit having an arithmetic function, such as a CPU or a GPU. The memory circuit is a memory circuit including a Si transistor, such as a DRAM or an SRAM, or a memory circuit including a transistor with an oxide semiconductor in a semiconductor layer including a channel formation region (an OS transistor), such as a DOSRAM or a NOSRAM described later. The driver circuit is a circuit for driving another circuit such as a memory circuit. The peripheral circuit is a circuit that may perform lower-speed processing than the arithmetic circuit, such as a LAN (Local Area Network), a USB (Universal Serial Bus), or a PCI (Peripheral Component Interconnect). In addition, a circuit such as an interface or a bridge circuit can be used as the functional circuit.

As described above, the semiconductor device 10 of one embodiment of the present invention includes the base die 20 including the power supply circuit 21 that generates the constant voltage Vin and the reference voltage Vref, the die 30_2 including the power supply circuit 31 that generates the constant voltage Vout by being supplied with the constant voltage Vin and the reference voltage Vref, and the dies 30_1 and 30_3 each including the functional circuit 32 that operates by being supplied with the constant voltage Vout. The dies 30_1 to 30_3 each include the through electrodes 41A and 41B. The die 30_2 is provided over the base die, and the dies 30_1 and 30_3 are provided in contact with the upper layer or the lower layer of the die 30_2. The base die 20 and the die 30_2 are electrically connected via the through electrode 41A. The die 30_2 and the dies 30_1 and 30_3 are electrically connected via the through electrode 41B.

In the semiconductor device of one embodiment of the present invention, in the structure in which the plurality of dies are three-dimensionally stacked over the base die, uniformity of voltage supplied from the power supply circuit can be easily ensured in power management in the Z direction. While supplying a voltage needed for generating a constant voltage to a die that is away from the base die, the power supply circuit and the functional circuit can be provided close to each other. Furthermore, the plurality of functional circuits 32 can be provided at an equal distance from the power supply circuit 31, so that the semiconductor device with excellent uniformity of voltage supplied to the functional circuits 32 can be provided.

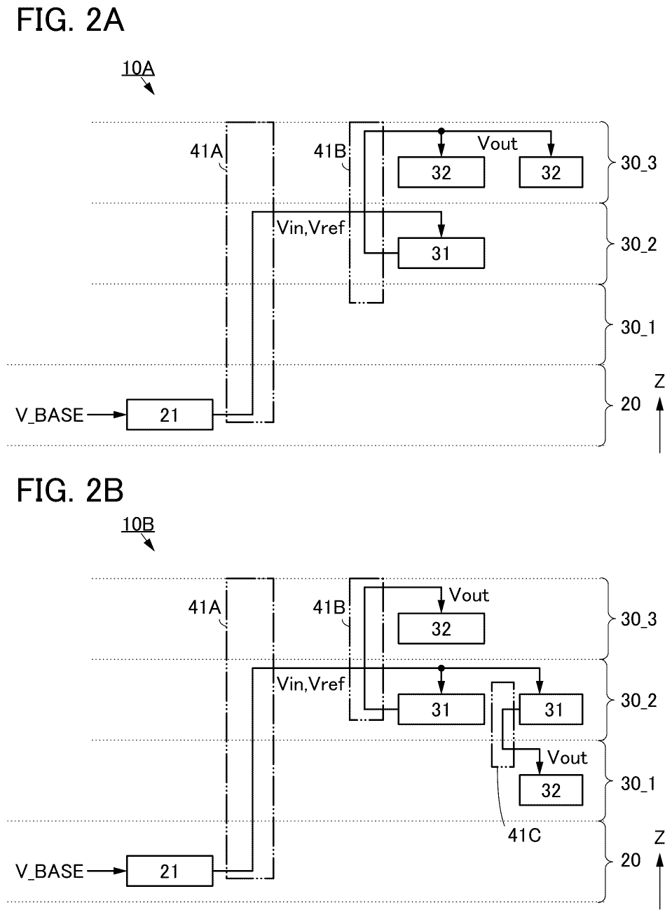

Although FIG. 1B illustrates the structure in which the functional circuits 32 are provided in the dies 30_1 and 30_3 in the upper layer and the lower layer of the die 30_2 including the power supply circuit 31, the functional circuit 32 may be provided in either one of them. For example, as in a semiconductor device 10A illustrated in FIG. 2A, a structure in which the functional circuit 32 is not provided in the die 30_1 can be employed.

Although FIG. 1B illustrates a structure in which the die 30_2 including the power supply circuit 31 is electrically connected to the functional circuits 32 provided in the dies 30_1 and 30_3 in the upper layer and the lower layer of the die 30_2 via the through electrode 41B, another structure may be employed. For example, as in a semiconductor device 10B illustrated in FIG. 2B, a structure in which the functional circuit 32 included in the die 30_3 in the upper layer is connected to the power supply circuit 31 via the through electrode 41B, and the functional circuit 32 included in the die 30_1 in the lower layer is connected to the power supply circuit 31 via a through electrode 41C can be employed. As illustrated in FIG. 2B, a structure in which the power supply circuit 31 included in the die 30_2 is provided for each functional circuit 32 can be provided.

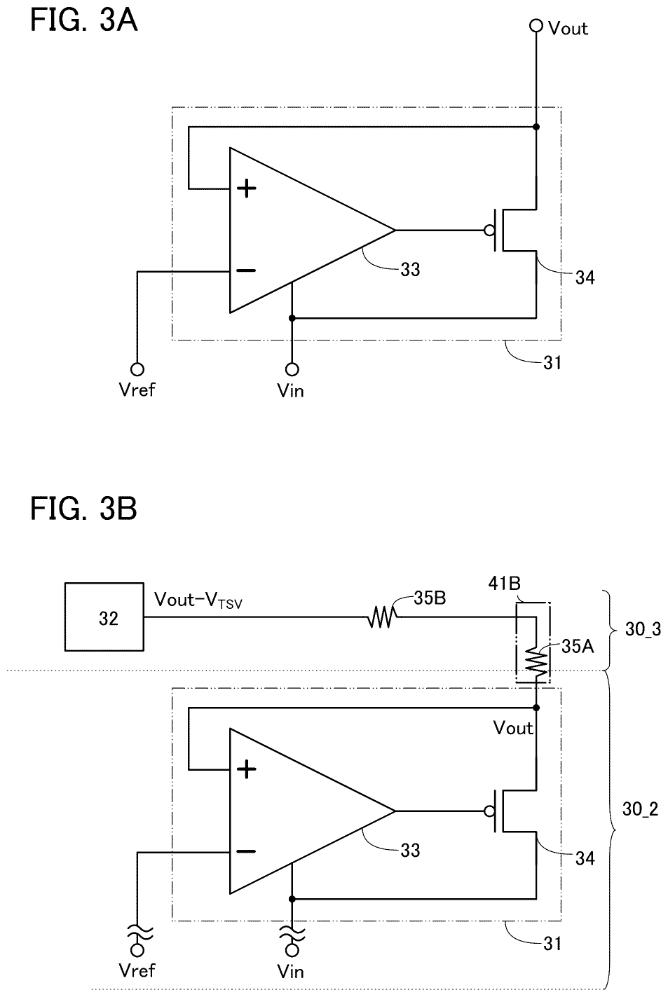

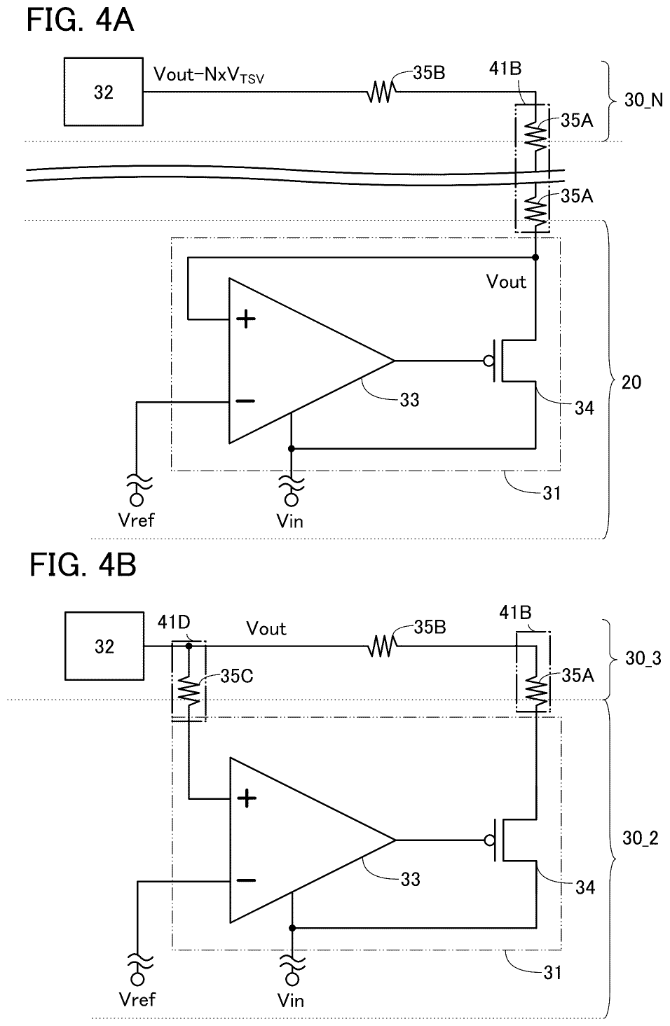

The structure in FIG. 2B is excellent in increasing accuracy of voltage supplied to the functional circuit 32. In FIG. 3A to FIG. 4B, structure examples of the power supply circuits 31 and advantages of placing the power supply circuit 31 in the vicinity of the functional circuit 32 are described.

FIG. 3A is a diagram illustrating a circuit structure of an LDO regulator applicable to the power supply circuit 31. As described above, in the structure in which the plurality of dies are three-dimensionally stacked over the base die, the power supply circuit 31 includes an amplifier circuit 33 and a transistor 34 that is a p-channel Si transistor. The transistor 34 is a transistor for controlling output voltage. The voltage Vin and the reference voltage Vref are supplied from the power supply circuit 21 included in the base die 20, and the constant voltage Vout is supplied. The voltage of a wiring for supplying the constant voltage Vout is fed back to the amplifier circuit 33. The amplifier circuit 33 can control a gate voltage of the transistor 34 on the basis of a fed-back voltage and can supply a desired constant voltage Vout. Note that in FIG. 3A and the like, the constant voltage Vout that is fed back to the amplifier circuit 33 is input as a voltage divided with the GND potential.

In the structure of the power supply circuit illustrated in FIG. 3A, in the wiring for supplying the constant voltage Vout to the functional circuit 32 included in the die 30_3 in the upper layer (or the die 30_1 in the lower layer), a voltage drop occurs due to a resistor 35A included in the through electrode 41B and a resistor 35B included in a wiring in the die 30_3 including the functional circuit 32 (FIG. 3B). Thus, as illustrated in FIG. 3B, the constant voltage Vout output from the power supply circuit 31 is supplied to the functional circuit 32 as a voltage Vout-V_{TSV} (V_{TSV} corresponds to a voltage drop in the resistor 35A and the resistor 35B). That is, in the amplifier circuit 33 in the power supply circuit 31 included in the die 30_2, the voltage Vout-V_{TSV} is not fed back in some cases.

In the structure in which a desired voltage is not fed back to the amplifier circuit 33, a voltage drop becomes more noticeable when the distance between the power supply circuit 31 and the functional circuit 32 is long. For example, as illustrated in FIG. 4A, in the case where the power supply circuit 31 is provided in the base die 20 and the uppermost die 30 which includes the functional circuit 32 supplied with the constant voltage Vout is a die 30_N (Nis an integer greater than or equal to 2), a voltage drop is noticeable due to the resistors 35A and 35B of the through electrodes 41B provided in each of the N layers of the dies. Specifically, as illustrated in FIG. 4A, the constant voltage Vout output from the power supply circuit 31 is supplied to the functional circuit 32 as a voltage Vout-N×V_{TSV}. That is, in the amplifier circuit 33 in the power supply circuit 31 included in the die 30_2, a difference between the voltage Vout that is fed back and the voltage Vout-N×V_{TSV} that is supplied to the functional circuit 32 cannot be ignored.

In the structure of one embodiment of the present invention, the die 30_2 including the power supply circuit 31 that generates the constant voltage Vout by being supplied with the constant voltage Vin and the reference voltage Vref and the dies 30_1 and 30_3 each including the functional circuit 32 that operates by being supplied with the constant voltage Vout can be provided to be close to each other and to be in contact with the upper layer or the lower layer. Thus, the difference between the voltage Vout that is fed back and the voltage supplied to the functional circuit 32 can be small.

Specifically, as in a schematic circuit diagram illustrated in FIG. 4B, the functional circuit 32 and an input terminal of the amplifier circuit 33 can be placed close to each other, and a voltage can be fed back to the amplifier circuit 33 via a through electrode 41D different from the through electrode 41B. Although the fed-back voltage drops by an amount corresponding to a resistor 35C in the through electrode 41D, the amount of the voltage drop is reduced by an amount corresponding to the resistor 35B required for wiring routing in the die 30_3. Thus, a voltage close to the constant voltage Vout supplied to the functional circuit 32 can be fed back to the amplifier circuit 33.

Although FIG. 1A illustrates the power supply circuit 31 that supplies the constant voltage Vout on the basis of the constant voltage Vin and the reference voltage Vref, a plurality of power supply circuits 31 may be provided and a plurality of constant voltages may be supplied to the functional circuits.

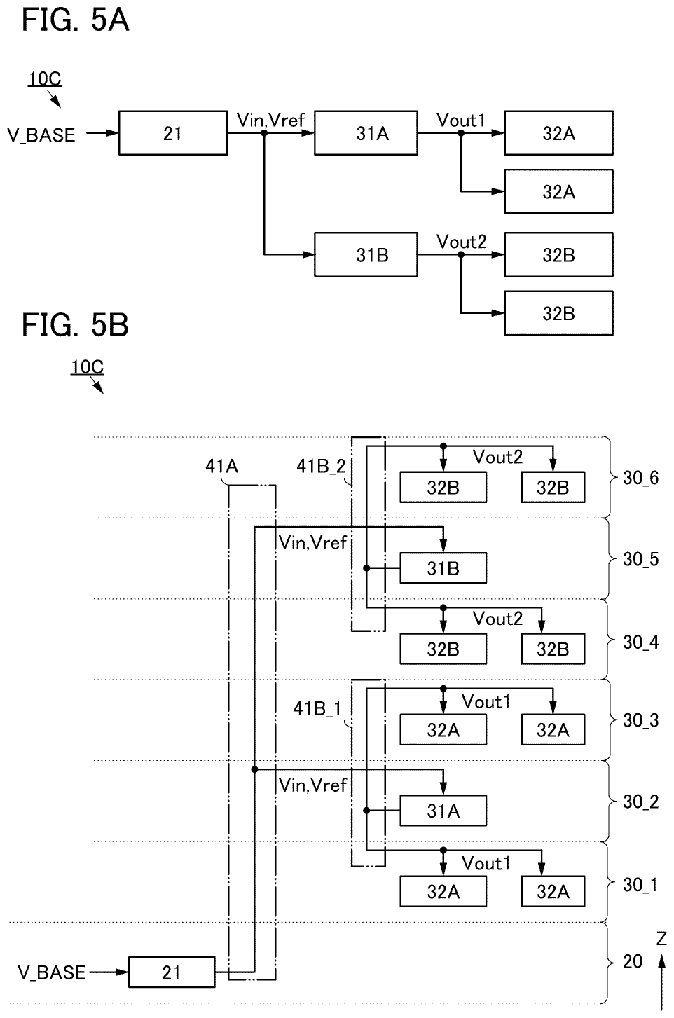

FIG. 5A is a block diagram of a semiconductor device 10C including a power supply circuit 31A that supplies a constant voltage Vout1 to a functional circuit 32A on the basis of the constant voltage Vin and the reference voltage Vref, and a power supply circuit 31B that supplies a constant voltage Vout2 to a functional circuit 32B on the basis of the constant voltage Vin and the reference voltage Vref.

Each structure in FIG. 5A can be placed in a plurality of dies (e.g., 30_1 to 30_6) over the base die 20 as in a schematic diagram illustrated in FIG. 5B. In the structure of FIG. 5B, the die 30_2 including the power supply circuit 31A is provided, and the constant voltage Vout1 is supplied from the power supply circuit 31 included in the die 30_2 away from the base die 20 to the functional circuits 32A included in the dies 30_1 and 30_3 close to the die 30_2. Similarly, in the structure of FIG. 5B, the die 30_5 including the power supply circuit 31B is provided, and the constant voltage Vout2 is supplied from the power supply circuit 31 included in the die 30_5 away from the base die 20 to the functional circuits 32B included in the dies 30_4 and 30_6 close to the die 30_5. The base die 20, the die 30_2, and the die 30_5 are electrically connected via the through electrode 41A. The die 30_2 and the dies 30_1 and 30_3 are electrically connected via a through electrode 41B_1. The die 30_5 and the dies 30_4 and 30_6 are electrically connected via a through electrode 41B_2.

With the structure illustrated in FIG. 5A and FIG. 5B, in the structure in which a plurality of dies are three-dimensionally stacked over the base die, uniformity of voltage supplied from the power supply circuit can be easily ensured in power management in the Z direction. While supplying a voltage needed for generating a constant voltage to a die that is away from the base die, the power supply circuit and the functional circuit can be provided close to each other. Furthermore, the plurality of functional circuits 32A and 32B can be arranged at an equal distance from the power supply circuits 31A and 31B, so that the semiconductor device with excellent uniformity of voltage supplied to the functional circuits 32A and the 32B can be provided.

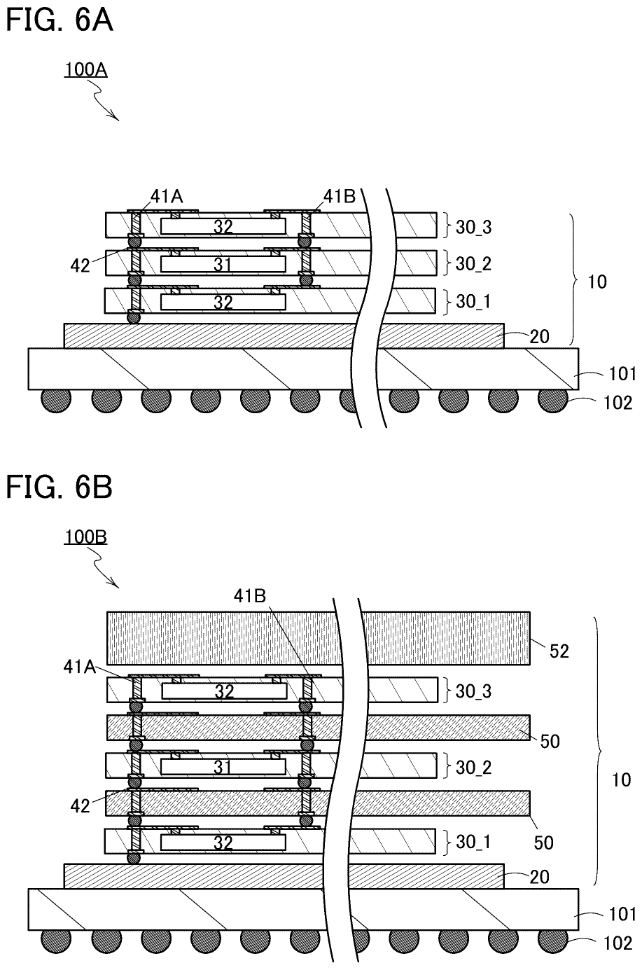

FIG. 6A and FIG. 6B each illustrate an example of an integrated circuit (referred to as an IC chip) including the above-described semiconductor device 10. The semiconductor device 10 can be one IC chip by mounting a plurality of dies on a packaging substrate. FIG. 6A and FIG. 6B each illustrate an example of the structure.

A schematic cross-sectional view of an IC chip 100A illustrated in FIG. 6A illustrates the semiconductor device 10 in which the base die 20 is provided over a packaging substrate 101 and three layers of dies, 30_1 to 30_3, are stacked over the base die 20, for example. Solder balls 102 for connecting the IC chip 100A to a printed circuit board or the like are provided on the packaging substrate 101. The dies 30_1 to 30_3 can be connected to the base die 20 via the through electrodes 41A and 41B provided to penetrate the dies 30_1 to 30_3. In addition, the layers can be electrically connected to each other via metal bumps 42 (also referred to as micro-bumps) provided between the through electrodes 41A and 41B provided to penetrate the layers.

Note that in the dies 30_1 to 30_3, a structure without using the metal bumps 42 may be employed. In that case, a structure in which the dies are attached to each other so that the electrodes exposed to the surfaces are electrically bonded may be employed. As a technique for electrically bonding different layers using the electrodes exposed to the surfaces, Cu—Cu bonding can be used. The Cu-Cu bonding is a technique that establishes electrical continuity by connecting Cu (copper) pads.

In a schematic cross-sectional view of an IC chip 100B illustrated in FIG. 6B as another example, in the structure in which the dies 30_1 to 30_3 illustrated in FIG. 6A are stacked, heat diffusion layers 50 are provided between the die 30_1 and the die 30_2 and between the die 30_2 and the die 30_3, and a heat radiation layer 52 is provided in the upper layer of the dies 30_1 to 30_3. It is preferable that thermal conductivity between the heat diffusion layer 50 and the heat radiation layer 52 be increased by connecting the heat diffusion layer 50 and the heat radiation layer 52 via metal bumps and through electrodes, for example.

Each of the heat diffusion layer 50 and the heat radiation layer 52 is preferably formed using a material having high thermal conductivity, and can be formed of a metal layer or a layer containing an organic material, for example. A heat radiation property is preferably improved by providing a heat sink or the like in the upper layer of the heat radiation layer. The heat radiation layer 52 is preferably a layer having high adhesion with the heat sink or the like.

Compared to the switching regulator, the series regulator that can be used for the power supply circuit 31 can be made small, but the conversion efficiency of the series regulator is low. Therefore, heat generation is likely to occur in the process of generating the constant voltage Vout. Accordingly, using the heat diffusion layer 50 and the heat radiation layer 52 to promote heat radiation enables the semiconductor device and the IC chip to have high reliability.

As described above, in one embodiment of the present invention, in the structure in which the plurality of dies are three-dimensionally stacked over the base die, uniformity of voltage supplied from the power supply circuit in the Z direction can be easily ensured. While supplying a voltage needed for generating a constant voltage to a die that is away from the base die, the power supply circuit and the functional circuit can be provided close to each other. Furthermore, since a plurality of functional circuits can be arranged at an equal distance from the power supply circuit, the semiconductor device can have excellent uniformity of voltage supplied to the functional circuits 32.

This embodiment can be implemented in combination with the other embodiments described in this specification as appropriate.

### Embodiment 2

In this embodiment, a modification example of the semiconductor device described in the above embodiment is described. Components in common with those in Embodiment 1 are denoted by common reference numerals, and description thereof is omitted.

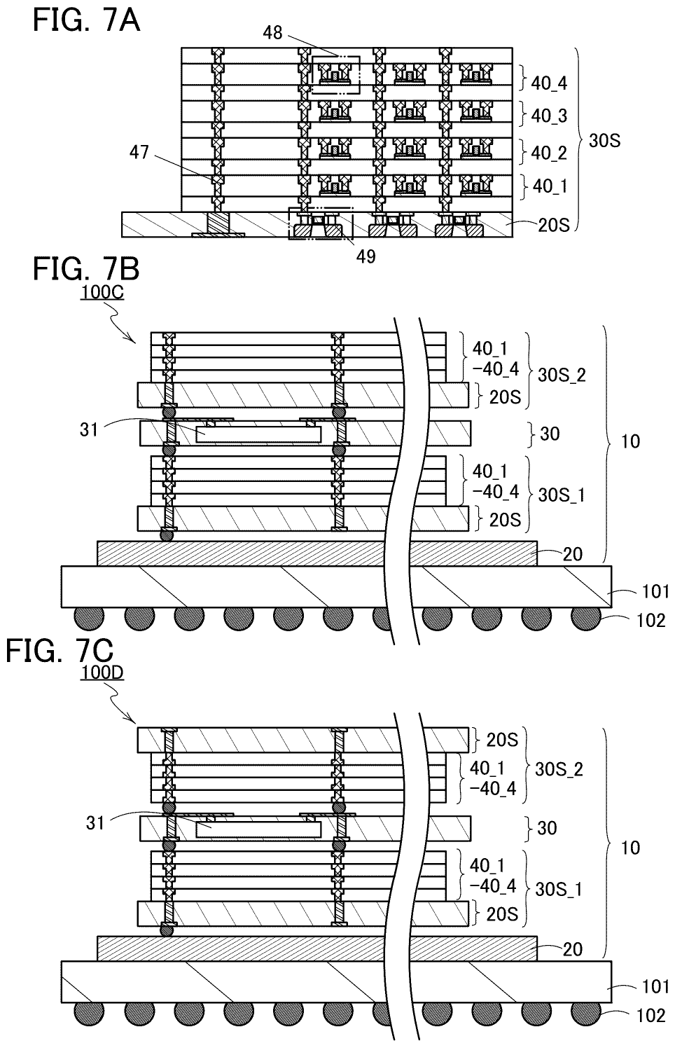

FIG. 7A is a schematic cross-sectional view illustrating a modification example of a die that can be stacked over a base die included in a semiconductor device 10. FIG. 7B and FIG. 7C are schematic cross-sectional views of a semiconductor device in which the structure of FIG. 7A is applied to a schematic cross-sectional view of the semiconductor device 10 mounted on the IC chip described with reference to FIG. 6A.

In a die 30S illustrated in FIG. 7A, element layers 40_1 to 40_4 including OS transistors 48 are provided over a base die 20S including Si transistors 49. Electrodes 47 for electrically connecting the base die 20S and the element layers 40_1 to 40_4 can be provided in a step of manufacturing the Si transistors 49 or the OS transistors 48. In this embodiment and the like, the number of element layers illustrated as the element layers 40_1 to 40_4 is not limited to four, and two or more is applicable. Note that in the case where matters common to the element layers 40_1 to 40_4 are described, the term “element layer 40” is merely used in some cases.

The structure of FIG. 7A can be a monolithic structure in which a technique using a through electrodes such as a TSV or a Cu—Cu direct bonding technique is not used for connecting the base die 20S including the Si transistors 49 and the element layers 40_1 to 40_4 including the OS transistors. In the element layers 40_1 to 40_4 over the base die 20S, wirings provided together with the OS transistors 48 included in the element layers 40_1 to 40_4 can be used as the electrodes 47 for being connected with the element layers in the upper layer or the lower layer.

The distance between the wirings provided together with the OS transistors 48 can be more miniaturized than the distance between TSVs or through electrodes used in the Cu—Cu direct bonding technique. Thus, in the structure of the die 30S illustrated in FIG. 7A, the number of electrodes for being connected with the element layers in the upper layer or the lower layer can be increased. Accordingly, the number of wirings (the number of signal lines) of the functional circuits provided in the element layers 40_1 to 40_4 and the functional circuit provided in the base die 20S can be increased. In other words, the number of channels between the functional circuits can be increased. Therefore, the transfer amount (bandwidth) of signals transmitted and received between functional circuits can be increased. By increasing the bandwidth, the data transfer amount per unit time can be increased.

Examples of a metal oxide used in the OS transistors include indium oxide, gallium oxide, and zinc oxide. The metal oxide preferably contains two or three kinds selected from indium, an element M, and zinc. The element M is one or more kinds of elements selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide. Alternatively, it is preferable to use an oxide containing indium, tin, and zinc (also referred to as ITZO). Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO). Further alternatively, it is preferable to use an oxide containing indium (In), gallium (Ga), zinc (Zn), and tin (Sn) (also referred to as IGZTO).

The metal oxide used in the OS transistors may include two or more metal oxide layers with different compositions. For example, a stacked structure of a first metal oxide layer having In: M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be favorably employed.

Alternatively, a stacked structure of one selected from indium oxide, indium gallium oxide, and IGZO, and one selected from IAZO, IAGZO, and ITZO may be employed, for example.

The metal oxide used in the OS transistors preferably has crystallinity. Examples of an oxide semiconductor having crystallinity include a CAAC (c-axis aligned crystalline)-OS and an nc (nanocrystalline)-OS. When the oxide semiconductor having crystallinity is used, the semiconductor device can have high reliability.

In addition, the OS transistor operates stably even in a high-temperature environment and has small fluctuation in characteristics. For example, the off-state current hardly increases even in the high-temperature environment. Specifically, the off-state current hardly increases even at an environment temperature higher than or equal to room temperature and lower than or equal to 200° C. In addition, the on-state current is unlikely to decrease even in a high-temperature environment. Thus, the memory cell including the OS transistor achieves a stable operation and high reliability even in a high-temperature environment.

A functional circuit that can be provided in the element layer 40 including an OS transistor is preferably a memory circuit. As a memory cell that can be used for a memory circuit, a NOSRAM is preferably. NOSRAM (registered trademark) is an abbreviation for “Nonvolatile Oxide Semiconductor Random Access Memory (RAM)”. The memory cells of the NOSRAM are two-transistor (2T) or three-transistor (3T) gain cells.

An OS transistor has an extremely low current that flows between a source and a drain in an off state, that is, an extremely low leakage current. The NOSRAM can be used as a nonvolatile memory by retaining electric charge corresponding to data in the memory cells, using characteristics of extremely low leakage current. In particular, the NOSRAM is capable of reading retained data without destruction (non-destructive reading), and thus is suitable for arithmetic processing in which only a data reading operation is repeated many times.

FIG. 7B is a structure example of a schematic cross-sectional view of an IC chip 100C in which the die 30S of FIG. 7A and a die 30 including a power supply circuit 31 described in Embodiment 1 are combined.

In the IC chip 100C illustrated in FIG. 7B, a monolithic structure not employing the technique using the through electrodes such as the TSV or Cu—Cu direct bonding technique in the element layer is applied to the structure used for dies 30S_1 and 30S_2; thus, microfabrication of wirings provided in the element layer is possible. Thus, in the structure of the IC chip 100C illustrated in FIG. 7B, the number of electrodes for connecting with the element layers in the upper layer or the lower layer can be increased in the dies 30S_1 and 30S_2 each provided with the functional circuit. Therefore, the transfer amount (bandwidth) of signals transmitted and received between functional circuits can be increased and thus the data transfer amount per unit time can be increased.

The structure of the IC chip illustrated in FIG. 7B may be a structure of an IC chip 100D illustrated in FIG. 7C. FIG. 7C illustrates a structure in which the die 30S_2 provided in the upper layer and the die 30S_1 provided in the lower layer are placed to have symmetry with respect to the die 30. Specifically, the base die 20S provided in the lower layer (the die 30S_1), the element layers 40_1 to 40_4 provided in the lower layer (the die 30S_1), the die 30, the element layers 40_1 to 40_4 provided in the upper layer (the die 30S_2), and the base die 20S provided in the upper layer (the die 30S_2) are stacked in this order. With this structure, the uniformity of voltage supplied from the power supply circuit 31 to the functional circuits included in the dies 30S_1 and 30S_2 can be increased.

Next, a structure example of a functional circuit 32M that functions as a memory circuit in which the NOSRAM that can be applied to the element layers 40_1 to 40_4 including OS transistors is used as a memory cell is described.

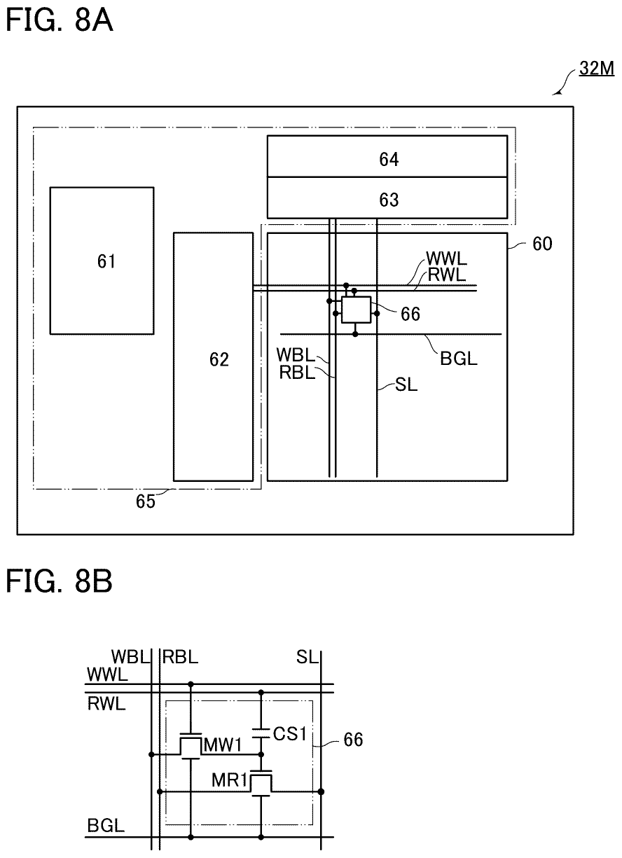

The functional circuit 32M illustrated in FIG. 8A includes a memory cell array 60 and a peripheral circuit 65. A control circuit 61, a row circuit 62, a column circuit 63, and an input/output circuit 64 are provided as the peripheral circuit 65.

The memory cell array 60 includes a memory cell 66, a word line RWL, a word line WWL, a bit line RBL, a bit line WBL, a source line SL, and a wiring BGL. The word line RWL is referred to as a read word line in some cases. The word line WWL is referred to as a write word line in some cases. The bit line RBL is referred to as a read bit line in some cases. The bit line WBL is referred to as a write bit line in some cases.

The control circuit 61 controls data writing and data reading. The control circuit 61 processes command signals from the outside (e.g., a chip enable signal, a write enable signal, and the like) and generates control signals for other circuits of the peripheral circuit 65.

The row circuit 62 has a function of selecting a row to be accessed. For example, the row circuit 62 includes a row decoder and a word line driver. The column circuit 63 has a function of precharging the bit lines WBL and RBL, a function of writing data to the bit line WBL, a function of amplifying data of the bit line RBL, a function of reading data from the bit line RBL, and the like. The input/output circuit 64 has a function of retaining write data, a function of retaining read data, and the like.

The structure of the peripheral circuit 65 is changed as appropriate depending on the structure, readout method, writing method, or the like of the memory cell array 60. Part of the peripheral circuit 65 is preferably provided in the base die 20S.

FIG. 8B illustrates a circuit structure example of the memory cell 66. The memory cell 66 here is a two-transistor (2T) gain cell. The memory cell 66 includes transistors MW1 and MR1 and a capacitor CS1. The transistor MW1 is a write transistor and the transistor MR1 is a read transistor. Back gates of the transistors MW1 and MR1 are electrically connected to the wiring BGL.

Since the write transistor is composed of an OS transistor, the memory cell 66 does not consume power for data retention. Thus, the memory cell 66 is a memory cell with low power consumption that can retain data for a long time, and the functional circuit 32M can be used as a nonvolatile storage device.

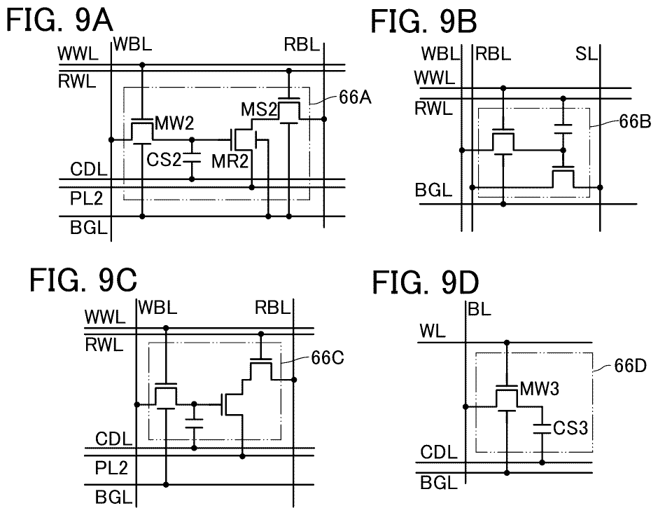

Other structure examples of a memory cell are described with reference to FIG. 9A to FIG. 9D.

A memory cell 66A illustrated in FIG. 9A is a 3T gain cell, which includes transistors MW2, MR2, and MS2, and a capacitor CS2. The transistors MW2, MR2, and MS2 are a write transistor, a read transistor, and a selection transistor, respectively. Back gates of the transistors MW2, MR2, and MS2 are electrically connected to the wiring BGL. The memory cell 66A is electrically connected to the word lines RWL and WWL, the bit lines RBL and WBL, a capacitor line CDL, and a power supply line PL2. For example, a voltage GND (low-level-side power supply voltage) is input to the capacitor line CDL and the power supply line PL2.

FIG. 9B illustrates the other structure example of a 2T gain cell. In a memory cell 66B illustrated in FIG. 9B, a read transistor is composed of an OS transistor that does not have a back gate.

FIG. 9C illustrates the other structure example of a 3T gain cell. In a memory cell 66C illustrated in FIG. 9C, each of a read transistor and a selection transistor is composed of an OS transistors that does not have a back gate.

In the above-described gain cells, a bit line serving as both the bit line RBL and the bit line WBL may be provided.

Although the NOSRAM is described as an example of a structure applicable to the memory cell 66, another structure may be employed as long as the memory cell can be formed using an OS transistor. For example, a DOSRAM that is a memory circuit including OS transistors may be used as well. The DOSRAM (registered trademark) is an abbreviation for “Dynamic Oxide Semiconductor RAM,” which indicates a RAM including a 1T (transistor) 1C (capacitor)-type memory cell. The DOSRAM is a DRAM formed using an OS transistor, and the DOSRAM is a memory that temporarily stores information sent from the outside. The DOSRAM is a memory utilizing a low off-state current of an OS transistor.

FIG. 9D illustrates an example of a 1TIC (capacitor) memory cell. A memory cell 66D illustrated in FIG. 9D is electrically connected to a word line WL, a bit line BL, the capacitor line CDL, and the wiring BGL. The memory cell 66D includes a transistor MW3 and a capacitor CS3. A back gate of the transistor MW3 is electrically connected to the wiring BGL.

In the case where the memory cell 66 is a NOSRAM or a DOSRAM, the wiring WWL connected to the gate of the transistor (the transistor MW1 in FIG. 8B) that is an access transistor is preferably supplied with a voltage that turns off the transistor, and the other portions are preferably power gated. With this structure, the supply of power supply voltages can be stopped while data is stored in the memory cell 66.

This embodiment can be implemented in combination with the other embodiments described in this specification as appropriate.

### Embodiment 3

In this embodiment, structures of transistors that can be used in the semiconductor device described in the above embodiments will be described. For example, a structure in which transistors having different electrical characteristics are provided to be stacked will be described. With the structure, the flexibility in design of the semiconductor device can be increased. When transistors having different electrical characteristics are provided to be stacked, the integration degree of the semiconductor device can be increased.

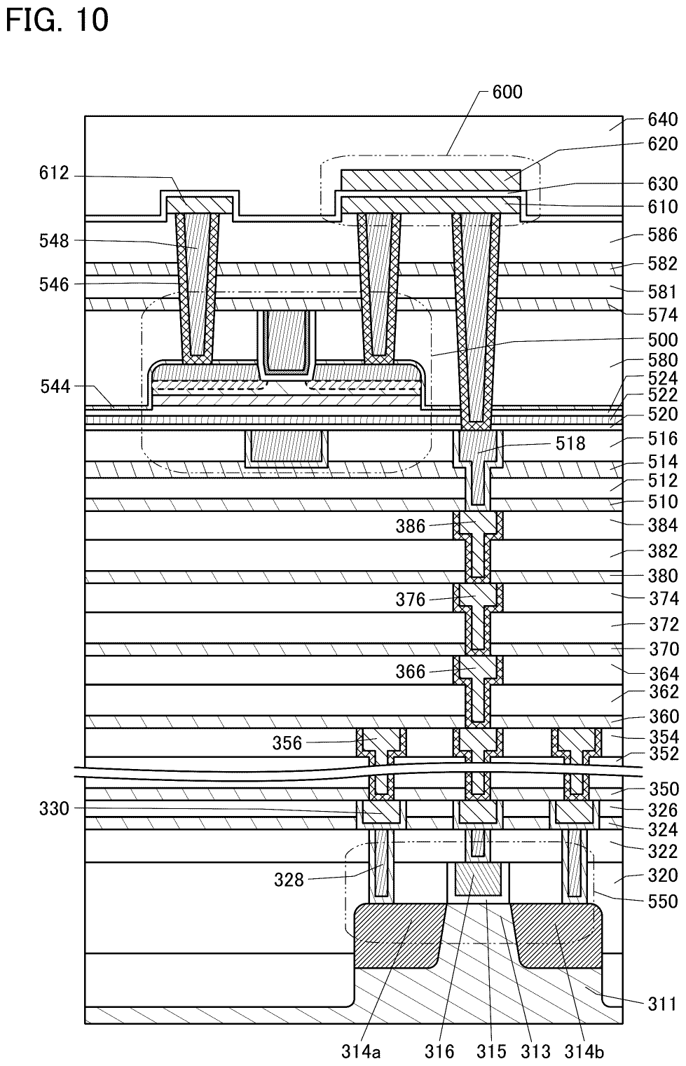

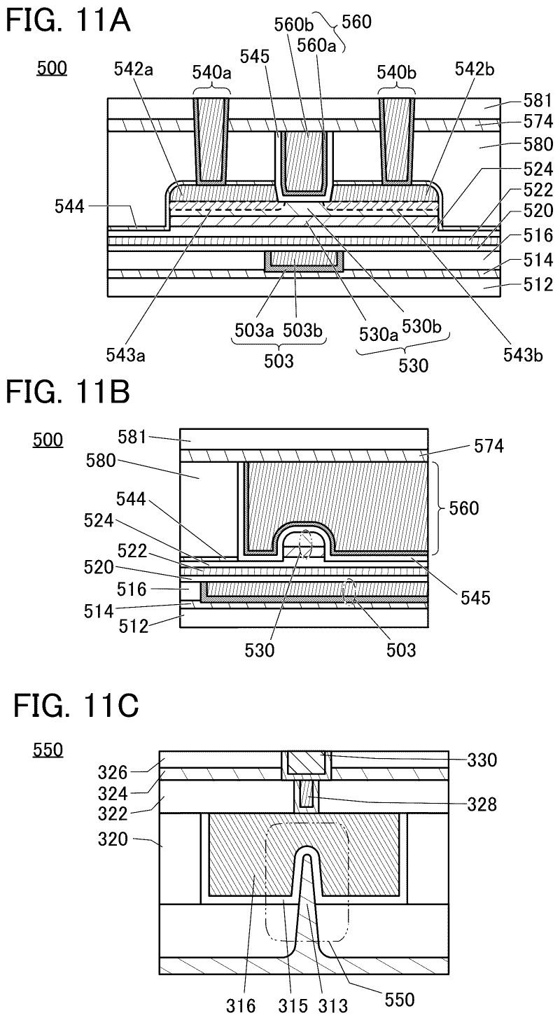

FIG. 10 illustrates part of a cross-sectional structure of a semiconductor device. The semiconductor device illustrated in FIG. 10 includes a transistor 550, a transistor 500, and a capacitor 600. FIG. 11A is a cross-sectional view of the transistor 500 in the channel length direction, FIG. 11B is a cross-sectional view of the transistor 500 in the channel width direction, and FIG. 11C is a cross-sectional view of the transistor 550 in the channel width direction. For example, the transistor 500 corresponds to the OS transistor described in the above embodiment and the transistor 550 corresponds to the Si transistor.

In FIG. 10, the transistor 500 is provided above the transistor 550, and the capacitor 600 is provided above the transistor 550 and the transistor 500.

The transistor 550 is provided in and on a substrate 311 and includes a conductor 316, an insulator 315, a semiconductor region 313 that is part of the substrate 311, and a low-resistance region 314a and a low-resistance region 314b functioning as a source region and a drain region.

As illustrated in FIG. 11C, the top surface and the side surface in the channel width direction of the semiconductor region 313 of the transistor 550 are covered with the conductor 316 with the insulator 315 positioned therebetween. Such a Fin-type transistor 550 can have an increased effective channel width and thus have improved on-state characteristics. In addition, contribution of an electric field of a gate electrode can be increased, so that the off-state characteristics of the transistor 550 can be improved.

Note that the transistor 550 may be either a p-channel transistor or an n-channel transistor.

It is preferable that a region of the semiconductor region 313 where a channel is formed, a region in the vicinity thereof, the low-resistance regions 314a and 314b functioning as the source and drain regions, and the like contain a semiconductor such as a silicon-based semiconductor, further preferably single crystal silicon. Alternatively, a material containing Ge (germanium), SiGe (silicon germanium), GaAs (gallium arsenide), GaAlAs (gallium aluminum arsenide), or the like may be contained. Silicon whose effective mass is adjusted by applying stress to the crystal lattice and thereby changing the lattice spacing may be contained. Alternatively, the transistor 550 may be a high electron mobility transistor (HEMT) with GaAs and GaAlAs, or the like.

The low-resistance regions 314a and 314b contain an element that imparts n-type conductivity, such as arsenic or phosphorus, or an element that imparts p-type conductivity, such as boron, in addition to a semiconductor material used for the semiconductor region 313.

The conductor 316 functioning as a gate electrode can be formed using a semiconductor material such as silicon containing the element that imparts n-type conductivity, such as arsenic or phosphorus, or the element that imparts p-type conductivity, such as boron, or a conductive material such as a metal material, an alloy material, or a metal oxide material.

Note that a material used for a conductor determines the work function; thus, selecting the material of the conductor can adjust the threshold voltage of a transistor. Specifically, titanium nitride, tantalum nitride, or the like is preferably used for the conductor. Furthermore, in order to ensure the conductivity and embeddability, a stacked layer of metal materials such as tungsten and aluminum is preferably used for the conductor. In particular, tungsten is preferably used in terms of heat resistance.

The transistor 550 may be formed using an SOI (Silicon on Insulator) substrate or the like.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate contains a single crystal semiconductor in a channel formation region.

An insulator 320, an insulator 322, an insulator 324, and an insulator 326 are provided to be stacked sequentially to cover the transistor 550.

The insulator 320, the insulator 322, the insulator 324, and the insulator 326 are formed using, for example, silicon oxide, silicon oxynitride, silicon nitride oxide, silicon nitride, aluminum oxide, aluminum oxynitride, aluminum nitride oxide, or aluminum nitride.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may function as a planarization film for eliminating a level difference caused by the transistor 550 or the like underlying the insulator 322. For example, the top surface of the insulator 322 may be planarized by planarization treatment using a chemical mechanical polishing (CMP) method or the like to increase the level of planarity.

The insulator 324 is preferably formed using a film having a barrier property that prevents hydrogen, impurities, or the like from diffusing from the substrate 311, the transistor 550, or the like into a region where the transistor 500 is provided.

For the film having a barrier property against hydrogen, for example, silicon nitride deposited by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. Specifically, the film that inhibits hydrogen diffusion is a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 1×10¹⁶ atoms/cm², preferably less than or equal to 5×10¹⁵ atoms/cm² in TDS analysis in a film-surface temperature range of 50° C. to 500° C., for example.

Note that the dielectric constant of the insulator 326 is preferably lower than that of the insulator 324. For example, the dielectric constant of the insulator 326 is preferably lower than 4, further preferably lower than 3. For example, the dielectric constant of the insulator 326 is preferably less than or equal to 0.7 times that of the insulator 324, further preferably less than or equal to 0.6 times that of the insulator 324. In the case where a material with a low dielectric constant is used for an interlayer film, the parasitic capacitance between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. In this specification and the like, a wiring and a plug connected to the wiring may be a single component. That is, part of a conductor functions as a wiring in some cases, and part of a conductor functions as a plug in other cases.

As a material for each of the plugs and wirings (e.g., the conductor 328 and the conductor 330), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in

FIG. 10. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. In such a structure, the transistor 550 and the transistor 500 can be separated by a barrier layer, so that the hydrogen diffusion from the transistor 550 into the transistor 500 can be inhibited.

Note that as the conductor having a barrier property against hydrogen, tantalum nitride is preferably used, for example. By stacking tantalum nitride and tungsten, which has high conductivity, hydrogen diffusion from the transistor 550 can be inhibited while the conductivity of a wiring is ensured. In that case, a tantalum nitride layer having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 10. Furthermore, a conductor 366 is formed in the insulator 360, the insulator 362, and the insulator 364. The conductor 366 functions as a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. In such a structure, the transistor 550 and the transistor 500 can be separated by a barrier layer, so that the hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 10. Furthermore, a conductor 376 is formed in the insulator 370, the insulator 372, and the insulator 374. The conductor 376 functions as a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. In such a structure, the transistor 550 and the transistor 500 can be separated by a barrier layer, so that the hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 10. Furthermore, a conductor 386 is formed in the insulator 380, the insulator 382, and the insulator 384. The conductor 386 functions as a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. In such a structure, the transistor 550 and the transistor 500 can be separated by a barrier layer, so that the hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. The number of wiring layers similar to the wiring layer including the conductor 356 may be three or less, or five or more.

An insulator 510, an insulator 512, an insulator 514, and an insulator 516 are stacked sequentially over the insulator 384. A material having a barrier property against oxygen, hydrogen, or the like is preferably used for any of the insulator 510, the insulator 512, the insulator 514, and the insulator 516.

For example, each of the insulator 510 and the insulator 514 is preferably formed using a film having a barrier property which prevents hydrogen, impurities, or the like from diffusing from the substrate 311, a region where the transistor 550 is provided, or the like into a region where the transistor 500 is provided. Therefore, a material similar to that for the insulator 324 can be used.

For the film having a barrier property against hydrogen, for example, silicon nitride deposited by a CVD method can be used. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. Specifically, the film that inhibits hydrogen diffusion is a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents permeation of both oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide contained in the transistor 500 can be prevented. Therefore, aluminum oxide is suitably used for a protective film of the transistor 500.

The insulator 512 and the insulator 516 can be formed using a material similar to that for the insulator 320, for example. In the case where a material with a relatively low dielectric constant is used for these insulators, the parasitic capacitance between wirings can be reduced. A silicon oxide film, a silicon oxynitride film, or the like can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 functions as a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. In such a structure, the transistor 550 and the transistor 500 can be separated by a layer having a barrier property against oxygen, hydrogen, and water, so that the hydrogen diffusion from the transistor 550 into the transistor 500 can be inhibited.

The transistor 500 is provided over the insulator 516.

As illustrated in FIGS. 11A and 11B, the transistor 500 includes the conductor 503 placed so as to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with an area between the conductor 542a and the conductor 542b, an insulator 545 placed on a bottom surface and a side surface of the opening, and a conductor 560 that is placed on a formation surface of the insulator 545.

As illustrated in FIGS. 11A and 11B, an insulator 544 is preferably placed between the insulator 580 and the oxide 530a, the oxide 530b, the conductor 542a, and the conductor 542b. In addition, as illustrated in FIGS. 11A and 11B, the conductor 560 preferably includes a conductor 560a provided inside the insulator 545 and a conductor 560b provided to be embedded inside the conductor 560a. Moreover, as illustrated in FIGS. 11A and 11B, an insulator 574 is preferably placed over the insulator 580, the conductor 560, and the insulator 545.

In this specification and the like, the oxide 530a and the oxide 530b may be collectively referred to as an oxide 530.

The transistor 500 has, in the region where the channel is formed and its vicinity, a structure in which the oxide 530a and the oxide 530b are stacked; however, the present invention is not limited thereto. For example, a single layer of the oxide 530b or a stacked-layer structure of three or more layers may be provided.

Although the conductor 560 has a two-layer structure in the transistor 500, the present invention is not limited thereto. For example, the conductor 560 may have a single-layer structure or a stacked-layer structure of three or more layers. The transistor 500 illustrated in FIG. 10 and FIG. 11A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b function as a source electrode and a drain electrode. As described above, the conductor 560 is embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the footprint of the transistor 500. Accordingly, miniaturization and high integration of the semiconductor device can be achieved.

In addition, since the conductor 560 is formed in the region between the conductor 542a and the conductor 542b in a self-aligned manner, the conductor 560 has neither a region overlapping with the conductor 542a nor a region overlapping with the conductor 542b. Thus, parasitic capacitance formed between the conductor 560 and each of the conductor 542a and the conductor 542b can be reduced. As a result, the transistor 500 can have increased switching speed and excellent frequency characteristics.

The conductor 560 functions as a first gate (also referred to as a top gate) electrode in some cases. The conductor 503 functions as a second gate (also referred to as a bottom gate) electrode in some cases. In that case, by changing a potential applied to the conductor 503 independently of a potential applied to the conductor 560, the threshold voltage of the transistor 500 can be controlled. In particular, when a negative potential is applied to the conductor 503, the threshold voltage of the transistor 500 can be increased to higher than 0 V, and the off-state current can be reduced. Thus, a drain current when a potential applied to the conductor 560 is 0 V can be smaller in the case where a negative potential is applied to the conductor 503 than in the case where the negative potential is not applied to the conductor 503

The conductor 503 is placed to overlap with the oxide 530 and the conductor 560. Accordingly, in the case where potentials are applied to the conductor 560 and the conductor 503, an electric field generated from the conductor 560 and an electric field generated from the conductor 503 are connected, thereby covering the channel formation region in the oxide 530.

In this specification and the like, a transistor structure in which a channel formation region is electrically surrounded by the electric field of a first gate electrode is referred to as a surrounded channel (S-channel) structure. The S-channel structure disclosed in this specification and the like is different from a Fin structure or a planar structure. The S-channel structure disclosed in this specification and the like can be regarded as a kind of the Fin structure. In this specification and the like, the Fin structure refers to a structure in which at least two surfaces (specifically, two surface, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Consequently, the density of current flowing through the transistor can be improved, so that the on-state current or the field-effect mobility of the transistor can be expected to increase.

The conductor 503 has a structure similar to that of the conductor 518; a conductor 503a is formed in contact with an inner wall of the opening in the insulator 514 and the insulator 516, and a conductor 503b is formed on the inner side. Although the transistor 500 having a structure in which the conductor 503a and the conductor 503b are stacked is described, the present invention is not limited thereto. For example, the conductor 503 may have a single-layer structure or a stacked-layer structure of three or more layers.

The conductor 503a is preferably formed using a conductive material having a function of inhibiting diffusion of impurities such as a hydrogen atom, a hydrogen molecule, a water molecule, and a copper atom (a conductive material through which the above impurities are less likely to pass). Alternatively, the conductor 503a is preferably formed using a conductive material having a function of inhibiting diffusion of oxygen (e.g., at least one of oxygen atoms, oxygen molecules, and the like) (a conductive material through which the above oxygen is less likely to pass). Note that in this specification, a function of inhibiting diffusion of impurities or oxygen means a function of inhibiting diffusion of any one or all of the above impurities and the above oxygen.

For example, when the conductor 503a has a function of inhibiting diffusion of oxygen, the conductivity of the conductor 503b can be prevented from being lowered because of oxidation.

In the case where the conductor 503 also functions as a wiring, the conductor 503b is preferably formed using a conductive material with high conductivity that contains tungsten, copper, or aluminum as its main component. Although the conductor 503 has a stacked layer of the conductor 503a and the conductor 503b in this embodiment, the conductor 503 may have a single-layer structure.

The insulator 520, the insulator 522, and the insulator 524 function as a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region containing excess oxygen (also referred to as an “excess-oxygen region”) is preferably formed in the insulator 524. When such an insulator containing excess oxygen is provided in contact with the oxide 530, oxygen vacancies (also referred to as Vo) in the oxide 530 can be reduced, leading to an improvement in reliability of the transistor 500. When hydrogen enters the oxygen vacancies in the oxide 530, such defects (hereinafter, referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of a transistor. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with sufficiently reduced impurities such as VoH is used for a channel formation region of a transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm^{3,} further preferably greater than or equal to 2.0×10¹⁹ atoms/cm³ or greater than or equal to 3.0×10²⁰ atoms/cm³ in TDS (Thermal Desorption Spectroscopy) analysis. In the TDS analysis, the film-surface temperature is preferably higher than or equal to 100° C. and lower than or equal to 700° C., or higher than or equal to 100° C. and lower than or equal to 400°° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen to be H₂O, and is removed from the oxide 530 or an insulator in the vicinity of the oxide 530 in some cases. In other cases, part of hydrogen is gettered by the conductor 542.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. The heat treatment is performed in a nitrogen gas atmosphere, an inert gas atmosphere, or an atmosphere containing an oxidizing gas at 10 ppm or more, 1% or more, or 10% or more.

For example, the heat treatment is preferably performed in an oxygen atmosphere. Accordingly, oxygen can be supplied to the oxide 530 to reduce oxygen vacancies (Vo). The heat treatment may be performed under a reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas atmosphere or an inert gas atmosphere.

Note that the oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, the insulator 522 preferably has a function of inhibiting diffusion of oxygen (e.g., oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen contained in the oxide 530 to the insulator 520 side is prevented. In addition, the conductor 503 can be inhibited from reacting with oxygen in the insulator 524, the oxide 530, or the like.

The insulator 522 preferably has a single-layer structure or a stacked-layer structure using an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr) TiO₃ (BST), for example. With miniaturization and high integration of a transistor, a problem such as generation of a leakage current sometimes arises because of a thin gate insulating film. When a high-k material is used for an insulator functioning as the gate insulating film, a gate potential at the time of operating the transistor can be reduced while the physical thickness of the gate insulating film is kept.

It is particularly preferable to use an insulator containing an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide containing aluminum and hafnium (hafnium aluminate), or the like is preferably used for the insulator containing an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, combination of an insulator which is a high-k material and silicon oxide or silicon oxynitride enables the insulator 520 to have a stacked-layer structure that is thermally stable and has a high dielectric constant.

Note that the transistor 500 in FIG. 11A and FIG. 11B includes the insulator 520, the insulator 522, and the insulator 524 as the second gate insulating film having a three-layer structure; however, the second gate insulating film may have a single-layer structure, a two-layer structure, or a stacked-layer structure of four or more layers. In that case, the stacked layers are not necessarily formed of the same material and may be formed of different materials.

In the transistor 500, a metal oxide functioning as an oxide semiconductor is used as the oxide 530 including a channel formation region. For example, as the oxide 530, a metal oxide such as an In—M—Zn oxide (M is one or more of aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an atomic layer deposition (ALD) method. Note that the metal oxide functioning as an oxide semiconductor will be described in detail in another embodiment.

The metal oxide functioning as the channel formation region in the oxide 530 has a band gap of 2 eV or more, preferably 2.5 eV or more. The use of a metal oxide having such a wide band gap can reduce the off-state current of a transistor.

When the oxide 530a is provided below the oxide 530b in the oxide 530, impurities can be inhibited from diffusing into the oxide 530b from the components formed below the oxide 530a.

The oxide 530 preferably has a structure including a plurality of oxide layers that differ in the atomic ratio of metal atoms. Specifically, the atomic ratio of an element M to constituent elements in the metal oxide used as the oxide 530a is preferably greater than that in the metal oxide used as the oxide 530b. Moreover, the atomic ratio of the element M to In in the metal oxide used as the oxide 530a is preferably greater than that in the metal oxide used as the oxide 530b. Moreover, the atomic ratio of In to the element M in the metal oxide used as the oxide 530b is preferably greater than that in the metal oxide used as the oxide 530a.

The energy of the conduction band minimum of the oxide 530a is preferably higher than that of the oxide 530b. In other words, the electron affinity of the oxide 530a is preferably smaller than that of the oxide 530b.

Here, the energy level of the conduction band minimum is gradually varied at a junction portion of the oxide 530a and the oxide 530b. In other words, the energy level of the conduction band minimum at a junction portion of the oxide 530a and the oxide 530b is continuously varied or continuously connected. To vary the energy level gradually, the density of defect states in a mixed layer formed at the interface between the oxide 530a and the oxide 530b is preferably made low.

Specifically, when the oxide 530a and the oxide 530b contain the same element (as a main component) in addition to oxygen, a mixed layer with a low density of defect states can be formed. For example, in the case where the oxide 530b is an In—Ga—Zn oxide, it is preferable to use an In—Ga—Zn oxide, a Ga-Zn oxide, gallium oxide, or the like as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Furthermore, a metal nitride film such as a tantalum nitride film is preferable because it has a barrier property against hydrogen or oxygen.

Although the conductor 542a and the conductor 542b have a single-layer structure in FIG. 11A, they may have a stacked-layer structure of two or more layers. For example, a tantalum nitride film and a tungsten film may be stacked. Alternatively, a titanium film and an aluminum film may be stacked. Other examples include a two-layer structure in which an aluminum film is stacked over a tungsten film, a two-layer structure in which a copper film is stacked over a copper-magnesium-aluminum alloy film, a two-layer structure in which a copper film is stacked over a titanium film, and a two-layer structure in which a copper film is stacked over a tungsten film.

Other examples include a three-layer structure in which a titanium film or a titanium nitride film and an aluminum film or a copper film are stacked so that the aluminum film or the copper film overlaps with the titanium film or the titanium nitride film and a titanium film or a titanium nitride film is further stacked thereover and a three-layer structure in which a molybdenum film or a molybdenum nitride film and an aluminum film or a copper film are stacked so that the aluminum film or the copper film overlaps with the molybdenum film or the molybdenum nitride film and a molybdenum film or a molybdenum nitride film is further stacked thereover. Note that a transparent conductive material containing indium oxide, tin oxide, or zinc oxide may be used.

As illustrated in FIG. 11A, a region 543a and a region 543b are sometimes formed as low-resistance regions at and near the interface between the oxide 530 and the conductor 542a (the conductor 542b). In that case, the region 543a functions as one of a source region and a drain region, and the region 543b functions as the other of the source region and the drain region. A channel formation region is formed in a region sandwiched between the region 543a and the region 543b.

When the conductor 542a (the conductor 542b) is provided in contact with the oxide 530, the oxygen concentration in the region 543a (the region 543b) sometimes decrease. In addition, a metal compound layer that contains the metal contained in the conductor 542a (the conductor 542b) and the component of the oxide 530 is sometimes formed in the region 543a (the region 543b). In such cases, the region 543a (the region 543b) has increased carrier density to be a low-resistance region.

The insulator 544 is provided to cover the conductor 542a and the conductor 542b and inhibits oxidation of the conductor 542a and the conductor 542b. Here, the insulator 544 may be provided to cover the side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 544. For the insulator 544, silicon nitride oxide or silicon nitride can be used, for example.

It is particularly preferable to use, as the insulator 544, aluminum oxide, hafnium oxide, an oxide containing aluminum and hafnium (hafnium aluminate), or the like that is an insulator containing an oxide of one or both of aluminum and hafnium. In particular, hafnium aluminate has higher heat resistance than a hafnium oxide film and thus is less likely to be crystallized by heat treatment in a later step. Note that the insulator 544 is not necessarily provided when the conductor 542a and the conductor 542b are oxidation-resistant materials or materials that do not significantly lose the conductivity even after absorbing oxygen. Design is determined as appropriate in consideration of required transistor characteristics.

The insulator 544 can inhibit impurities such as water and hydrogen contained in the insulator 580 from diffusing into the oxide 530b. Moreover, the oxidation of the conductor 542 due to excess oxygen contained in the insulator 580 can be inhibited.

The insulator 545 functions as a first gate insulating film. The insulator 545 is preferably formed using an insulator which contains excess oxygen and from which oxygen is released by heating, like the insulator 524.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which have thermal stability, are preferable.

When an insulator containing excess oxygen is provided as the insulator 545, oxygen can be effectively supplied from the insulator 545 to the channel formation region of the oxide 530b. As in the insulator 524, the concentration of impurities such as water and hydrogen in the insulator 545 is preferably lowered. The thickness of the insulator 545 is preferably greater than or equal to 1 nm and less than or equal to 20 nm.

Furthermore, in order that excess oxygen contained in the insulator 545 can be efficiently supplied to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, a reduction in the amount of excess oxygen supplied to the oxide 530 can be suppressed. Moreover, oxidization of the conductor 560 due to excess oxygen can be suppressed. For the metal oxide, a material that can be used for the insulator 544 is used.

Note that the insulator 545 may have a stacked-layer structure like the second gate insulating film. As miniaturization and high integration of transistors progress, a problem such as leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have a high dielectric constant.

Although the conductor 560 that functions as the first gate electrode and has a two-layer structure is shown in FIG. 11A and FIG. 11B, a single-layer structure or a stacked-layer structure of three or more layers may be employed.

The conductor 560a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, the conductivity of the conductor 560b can be prevented from being lowered because of oxidization due to oxygen contained in the insulator 545. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited by a sputtering method, the conductor 560a can have a reduced electrical resistance value to be a conductor. Such a conductor can be referred to as an OC (Oxide Conductor) electrode.

Furthermore, the conductor 560b is preferably formed using a conductive material containing tungsten, copper, or aluminum as its main component. In addition, the conductor 560b also functions as a wiring and thus a conductor having high conductivity is preferably used. For example, a conductive material containing tungsten, copper, or aluminum as its main component can be used. The conductor 560b may have a stacked-layer structure, for example, a stacked-layer structure of titanium or titanium nitride and any of the above conductive materials.

The insulator 580 is provided over the conductor 542a and the conductor 542b with the insulator 544 positioned therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because they are thermally stable. Silicon oxide and porous silicon oxide are particularly preferable because an excess-oxygen region can be formed easily in a later step. The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with a region between the conductor 542a and the conductor 542b. Thus, the conductor 560 is formed to be embedded in the opening of the insulator 580 and the region sandwiched between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surfaces of the insulator 580, the conductor 560, and the insulator 545. When the insulator 574 is deposited by a sputtering method, excess-oxygen regions can be provided in the insulator 545 and the insulator 580. Therefore, oxygen can be supplied from the excess-oxygen region to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Thus, aluminum oxide deposited by a sputtering method can serve as not only an oxygen supply source but also a barrier film against impurities such as hydrogen.

An insulator 581 functioning as an interlayer film is preferably provided over the insulator 574. As in the insulator 524 or the like, the concentration of impurities such as water and hydrogen in the insulator 581 is preferably lowered.

A conductor 540a and a conductor 540b are provided in the openings formed in the insulator 581, the insulator 574, the insulator 580, and the insulator 544. The conductor 540a and the conductor 540b are provided to face each other with the conductor 560 positioned therebetween. The conductor 540a and the conductor 540b have a structure similar to that of a conductor 546 and a conductor 548 described later.

An insulator 582 is provided over the insulator 581. A material having a barrier property against oxygen, hydrogen, or the like is preferably used for the insulator 582. Thus, the insulator 582 can be formed using a material similar to that for the insulator 514. For the insulator 582, a metal oxide such as aluminum oxide, hafnium oxide, or tantalum oxide is preferably used, for example.

In particular, aluminum oxide has an excellent blocking effect that prevents permeation of both oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide contained in the transistor 500 can be prevented. Therefore, aluminum oxide is suitably used for a protective film of the transistor 500.

An insulator 586 is provided over the insulator 582. The insulator 586 can be formed using a material similar to that for an insulator 320. In the case where a material with a relatively low dielectric constant is used for these insulators, the parasitic capacitance between wirings can be reduced. A silicon oxide film, a silicon oxynitride film, or the like can be used for the insulator 586, for example.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 function as plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as some of the manufacturing steps of the transistor 500. The insulator having a high barrier property against hydrogen or water is formed using a material similar to that for the insulator 522 or the insulator 514, for example.

The capacitor 600 is provided above the transistor 500. The capacitor 600 includes a conductor 610, a conductor 620, and an insulator 630.

A conductor 612 may be provided over the conductor 546 and the conductor 548. The conductor 612 functions as a plug or a wiring that is connected to the transistor 500. The conductor 610 functions as an electrode of the capacitor 600. The conductor 612 and the conductor 610 can be formed at the same time.

The conductor 612 and the conductor 610 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are illustrated in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap the conductor 610 with the insulator 630 therebetween. Note that the conductor 620 can be formed using a conductive material such as a metal material, an alloy material, or a metal oxide material. It is preferable to use a high-melting-point material that has both heat resistance and conductivity, such as tungsten or molybdenum, and it is particularly preferable to use tungsten. In the case where the conductor 620 is formed concurrently with another component such as a conductor, copper (Cu), aluminum (Al), or the like, which is a low-resistance metal material, may be used.

An insulator 640 is provided over the conductor 620 and the insulator 630. The insulator 640 can be formed using a material similar to that for the insulator 320. In addition, the insulator 640 may function as a planarization film that covers an uneven shape therebelow.

With the use of the structure, a semiconductor device that includes a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and a SOI (Silicon on Insulator) substrate. Alternatively, a plastic substrate having heat resistance to the processing temperature in this embodiment may be used. Examples of a glass substrate include barium borosilicate glass, aluminosilicate glass, aluminoborosilicate glass, and soda lime glass. Alternatively, crystallized glass or the like can be used.

Alternatively, a flexible substrate, an attachment film, paper including a fibrous material, a base film, or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Alternatively, polyamide, polyimide, an aramid resin, an epoxy resin, an inorganic vapor deposition film, and paper can be used. Specifically, the use of a semiconductor substrate, a single crystal substrate, an SOI substrate, or the like enables the manufacture of small-sized transistors with a small variation in characteristics, size, shape, or the like and with high current capability. A circuit using such transistors achieves lower power consumption or higher integration.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. The separation layer can be used when part or the whole of a semiconductor device formed over the separation layer is separated from the substrate and transferred to another substrate. In such a case, the transistor, the resistor, the capacitor, and/or the like can be transferred to a substrate having low heat resistance, a flexible substrate, or the like. Note that as the separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured, high heat resistance can be provided, or a reduction in weight or thickness can be achieved.

Providing a semiconductor device over a flexible substrate can suppress an increase in weight and can produce a non-breakable semiconductor device.

Note that the transistor 550 illustrated in FIG. 10 is just an example and the structure is not limited thereto; an appropriate transistor is used in accordance with a circuit structure, a driving method, or the like. For example, when the semiconductor device is a single-polarity circuit using only OS transistors (which mean transistors having the same polarity, e.g., only n-channel transistors), the transistor 550 has a structure similar to that of the transistor 500.

The configuration, structure, method, and the like described in this embodiment can be used in appropriate combination with the configurations, structures, methods, and the like described in the other embodiments, examples, and the like.

### Embodiment 4

In this embodiment, cross-sectional structure examples of a semiconductor device including OS transistors, which is a DOSRAM or a NOSRAM and described in the above embodiments, are described.

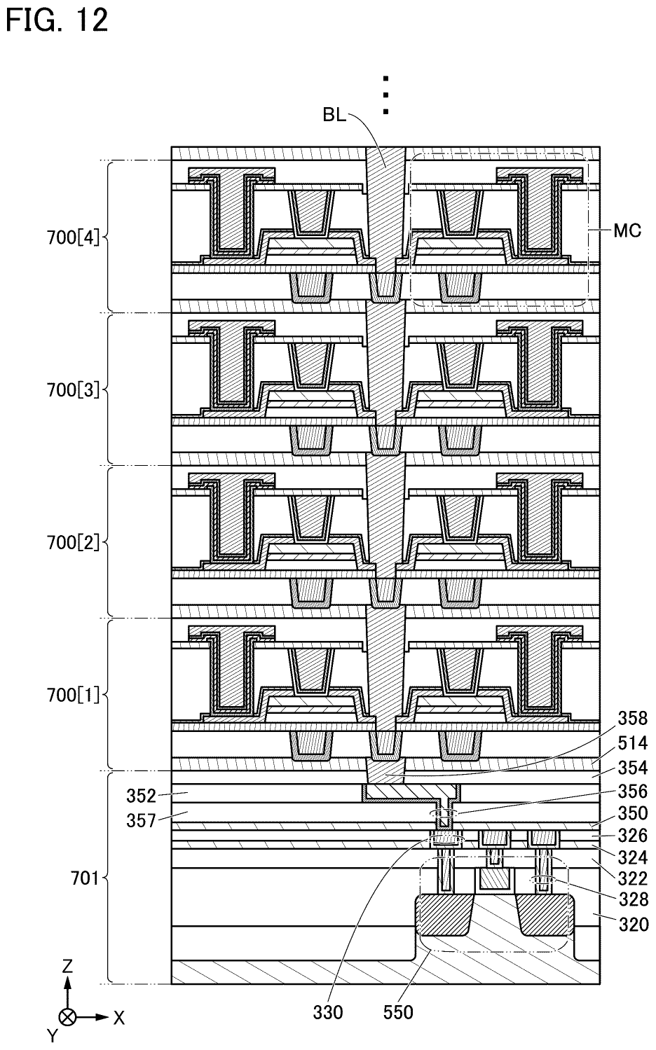

FIG. 12 illustrates a cross-sectional structure example of the case of using a DOSRAM circuit structure. In the example illustrated in FIG. 12, an element layer 700[1] to an element layer 700[4] are stacked over a driver circuit layer 701.

FIG. 12 illustrates a transistor 550 included in the driver circuit layer 701 as an example. The transistor 550 described in the above embodiment can be used as the transistor 550.

The transistor 550 illustrated in FIG. 12 is just an example and is not limited to the structure illustrated therein, and an appropriate transistor can be used in accordance with a circuit structure or a driving method.

A wiring layer provided with an interlayer film, a wiring, a plug, and the like may be provided between the driver circuit layer 701 and the element layers 700 or between a k-th element layer 700 and a k+1-th element layer 700. In this embodiment and the like, the k-th element layer 700 is referred to as an element layer 700[k], and the k+1-th element layer 700 is referred to as an element layer 700[k+1], in some cases. Here, k is an integer greater than or equal to 1 and less than or equal to N. In this embodiment and the like, the solutions of “k+a (a is an integer greater than or equal to 1)” and “k−a” are each an integer greater than or equal to 1 and less than or equal to N.

A plurality of wiring layers can be provided in accordance with the design. Furthermore, in this specification and the like, a wiring and a plug electrically connected to the wiring may be a single component. That is, part of a conductor functions as a wiring in some cases, and part of a conductor functions as a plug in other cases.

For example, an insulator 320, an insulator 322, an insulator 324, and an insulator 326 are stacked in this order over the transistor 550 as interlayer films. A conductor 328 or the like is embedded in the insulator 320 and the insulator 322. A conductor 330 or the like is embedded in the insulator 324 and the insulator 326. Note that the conductor 328 and the conductor 330 each function as a contact plug or a wiring.

The insulators functioning as the interlayer film may also function as a planarization film that covers an uneven shape therebelow. For example, a top surface of the insulator 320 may be planarized by planarization treatment using a chemical mechanical polishing (CMP) method to increase planarity.

A wiring layer may be provided over the insulator 326 and the conductor 330. For example, in FIG. 12, an insulator 350, an insulator 357, an insulator 352, and an insulator 354 are stacked in this order over the insulator 326 and the conductor 330. A conductor 356 is formed in the insulator 350, the insulator 357, and the insulator 352. The conductor 356 functions as a contact plug or a wiring.

Over the insulator 354, an insulator 514 included in the element layer 700[1] is provided. A conductor 358 is embedded in the insulator 514 and the insulator 354. The conductor 358 functions as a contact plug or a wiring. For example, a bit line BL and the transistor 550 are electrically connected to each other through the conductor 358, the conductor 356, the conductor 330, and the like.

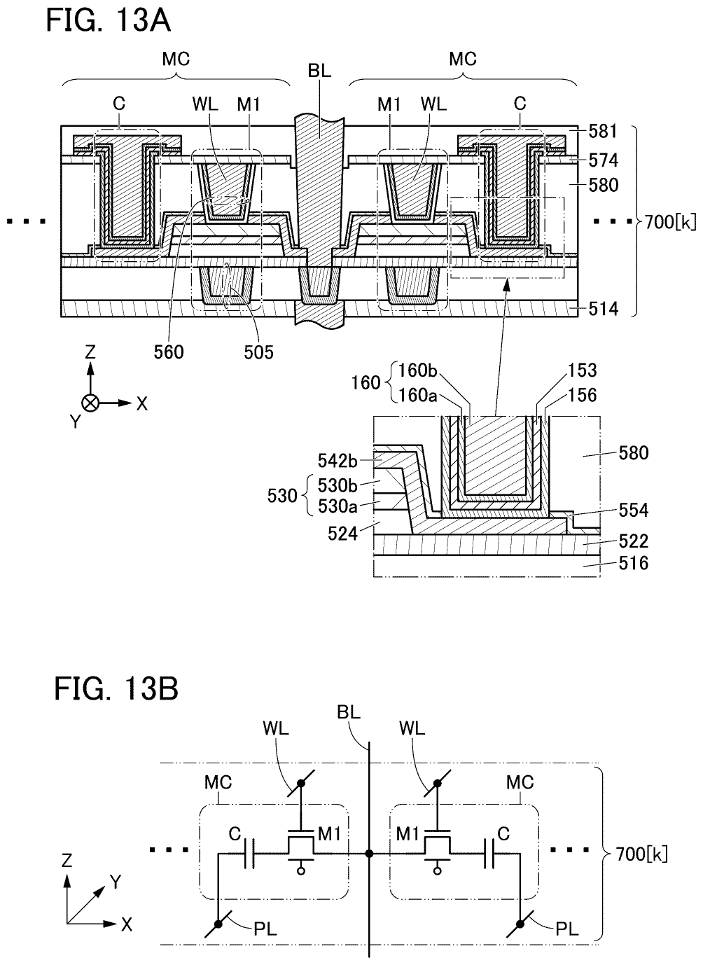

FIG. 13A illustrates a cross-sectional structure example of the element layer 700[k]. FIG. 13B is an equivalent circuit diagram of FIG. 13A. FIG. 13A illustrates an example where two memory cells MC are electrically connected to one bit line BL.

The memory cell MC illustrated in FIG. 12 and FIG. 13A includes a transistor M1 and a capacitor C. As the transistor M1, the transistor 500 described in the above embodiment can be used.

In this embodiment, a variation of the transistor 500 is illustrated as the transistor M1. Specifically, the transistor M1 is different from the transistor 500 in that a conductor 542a and a conductor 542b extend beyond an edge of a metal oxide 531.

The memory cell MC illustrated in FIG. 12 and FIG. 13A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. The conductor 160 is electrically connected to a wiring PL (not shown in FIG. 13A).

The capacitor C is formed in an opening portion that is provided by removal of part of an insulator 574, part of an insulator 580, and part of an insulator 554. Since the conductor 156, the insulator 153, and the conductor 160a are formed along a side surface of the opening portion, the conductor 156, the insulator 153, and the conductor 160a are preferably formed by an ALD method, a CVD method, or the like.

The conductor 156 and the conductor 160 may be formed using a conductor that can be used for a conductor 505 or a conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

For the insulator 153, an insulator of a high dielectric constant (high-k) material (material with a high relative permittivity) is preferably used. As the insulator of high dielectric constant material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, and nitride may contain silicon. Insulating layers each formed of any of the above-described materials can be stacked to be used.

As the insulator of high dielectric constant material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high dielectric constant material allows the insulator 153 to be thick enough to inhibit a leakage current and a sufficiently high capacitance of the capacitor C to be ensured.

It is preferable to use stacked insulating layers each formed of any of the above-described materials. A stacked-layer structure using a high dielectric constant material and a material having higher dielectric strength than the high dielectric constant material is preferably used. For example, as the insulator 153, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. An insulating film in which hafnium zirconium oxide, aluminum oxide, hafnium zirconium oxide, and aluminum oxide are stacked in this order can be used, for example. The stacking of such an insulator having relatively high dielectric strength, such as aluminum oxide, can increase the dielectric strength and inhibit electrostatic breakdown of the capacitor C.

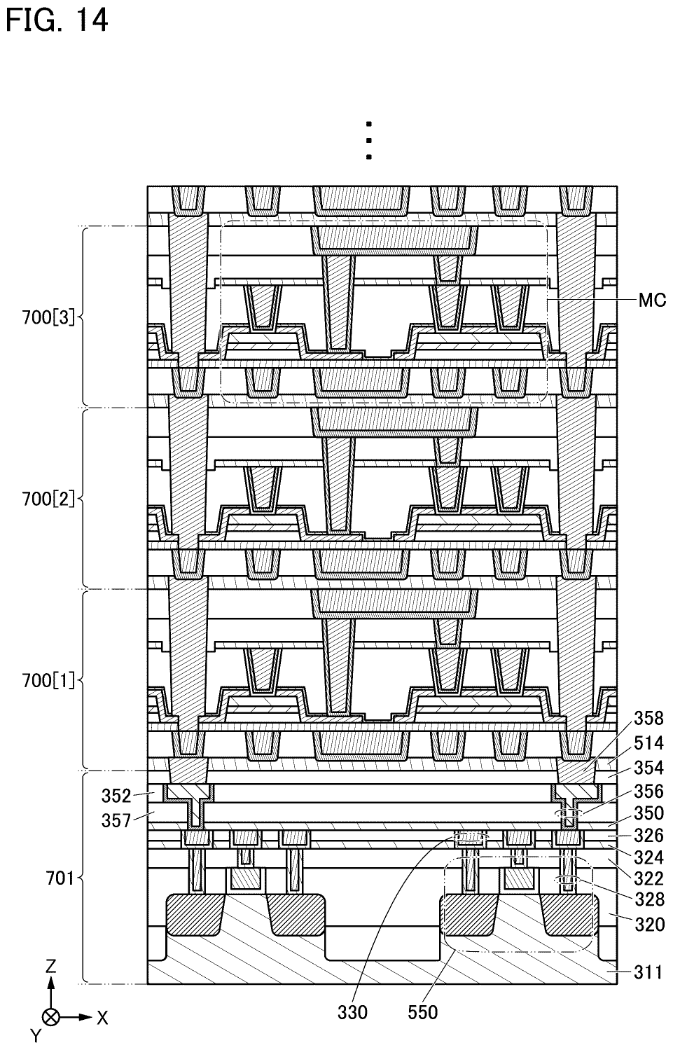

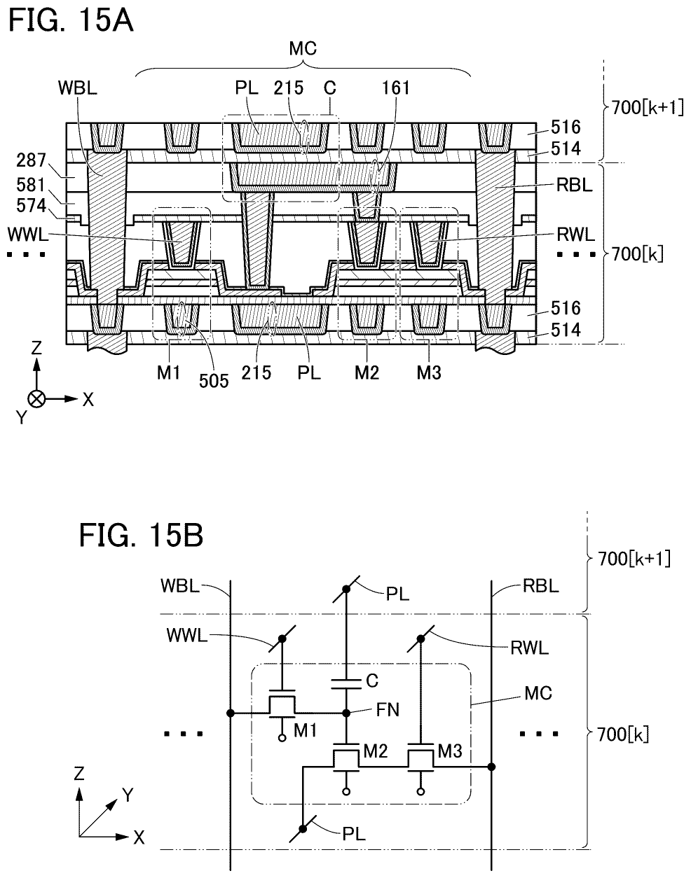

FIG. 14 illustrates a cross-sectional structure example of the case of using a NOSRAM memory cell circuit structure. FIG. 14 is also a variation of FIG. 12. FIG. 15A illustrates a cross-sectional structure example of the element layer 700[k]. FIG. 15B is an equivalent circuit diagram of FIG. 15A.

The memory cell MC illustrated in FIG. 14 and FIG. 15A includes the transistor M1, a transistor M2, and a transistor M3 over the insulator 514. A conductor 215 is provided over the insulator 514. The conductor 215 can be formed using the same material in the same process as those of the conductor 505 at the same time.

The transistor M2 and the transistor M3 illustrated in FIG. 14 and FIG. 15A share one island-shaped metal oxide 531. In other words, a part of the one island-shaped metal oxide 531 functions as a channel formation region of the transistor M2, and another part thereof functions as a channel formation region of the transistor M3. Furthermore, the source of the transistor M2 and a drain of the transistor M3 are shared, or the drain of the transistor M2 and a source of the transistor M3 are shared. Thus, the area occupied by the transistor M2 and the transistor M3 is smaller than that of the case where the transistor M2 and the transistor M3 are independently provided.

In the memory cell MC illustrated in FIG. 14 and FIG. 15A, an insulator 287 is provided over an insulator 581, and a conductor 161 is embedded in the insulator 287. The insulator 514 of the element layer 700[k+1] is provided over the insulator 287 and the conductor 161.

In FIG. 14 and FIG. 15A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. The other of a source and a drain of the transistor MI is electrically connected to the conductor 161 through a contact plug, and a gate of the transistor M2 is electrically connected to the conductor 161 through another contact plug.

This embodiment can be implemented in combination with the other embodiments described in this specification as appropriate.

### Embodiment 5

In this embodiment, a transistor whose channel formation region includes an oxide semiconductor (OS transistor) is described. Brief description is also made on comparison of an OS transistor with a transistor whose channel formation region includes silicon (also referred to as Si transistor).

### [OS Transistor]

An oxide semiconductor having a low carrier concentration is preferably used for the OS transistor. For example, the carrier concentration in a channel formation region of an oxide semiconductor is lower than or equal to 1×10¹⁸ cm-³, preferably lower than 1×10¹⁷ cm-³, further preferably lower than 1×10¹⁶ cm-³, still further preferably lower than 1×10¹³ cm-³, yet still further preferably lower than 1×10¹⁰ cm-³, and higher than or equal to 1×10⁻⁹ cm-³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In some cases, the OS transistor has defects that is oxygen vacancies in the oxide semiconductor into which hydrogen enters (hereinafter sometimes referred to as VoH), which generates electrons serving as carriers. When VoH is formed in the channel formation region, the donor concentration in the channel formation region is increased in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel is generated even when no voltage is applied to a gate electrode and a current flows through the transistor). Therefore, the impurities, oxygen vacancies, and VoH are preferably reduced as much as possible in the channel formation region of the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. This hinders miniaturization of a Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length needs to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-region and the source region and the drain region each become an n⁺ region in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during operation of the transistor and to the width of a bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has advantages over a Si transistor, such as a low off-state current and capability of having a short channel length.

The configurations, structures, methods, and the like described in this embodiment can be used in an appropriate combination with any of the configurations, structures, methods, and the like described in the other embodiments and the like.

### Embodiment 6

An electronic component, an electronic device, a large computer, a device for space, and a data center (also referred to as DC) for which the semiconductor device described in the above embodiments can be used will be described in this embodiment. An electronic component, an electronic device, a large computer, a device for space, and a data center each employing the semiconductor device of one embodiment of the present invention are effective in improving performance, for example, reducing power consumption.

### [Electronic Component]

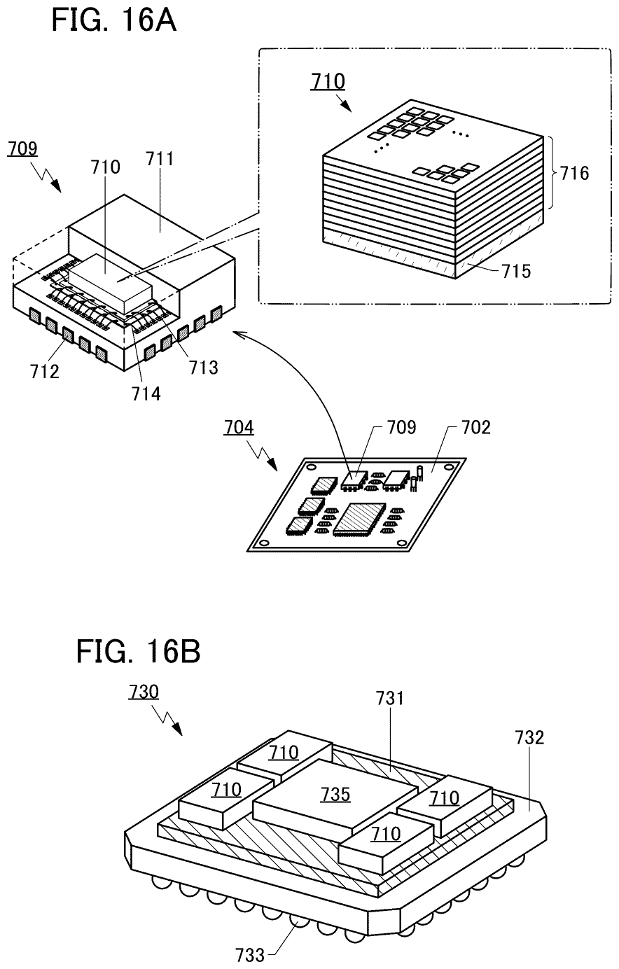

FIG. 16A is a perspective view of a substrate (a circuit board 704) provided with an electronic component 709. The electronic component 709 illustrated in FIG. 16A includes a semiconductor device 710 in a mold 711. Some components are omitted in FIG. 16A to show the inside of the electronic component 709. The electronic component 709 includes a land 712 outside the mold 711. The land 712 is electrically connected to an electrode pad 713, and the electrode pad 713 is electrically connected to the semiconductor device 710 through a wire 714. The electronic component 709 is mounted on a printed circuit board 702, for example.

A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using through electrode technique such as through-silicon via (TSV) technique and bonding technique such as Cu-Cu direct bonding. The monolithic stacked-layer structure of the driver circuit layer 715 and the memory layer 716, enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that a plurality of the memory cell arrays included in the memory layer 716 be formed with OS transistors and be monolithically stacked. The monolithic stacked-layer structure of memory cell arrays can improve the bandwidth of the memory and/or the access latency of the memory. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 16B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a central processing unit (CPU), a graphics processing unit (GPU), or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. A plurality of the wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure obtained by combining a stacked-layer of memory cell arrays formed by TSV and a monolithic stacked-layer of memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 16B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods other than BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

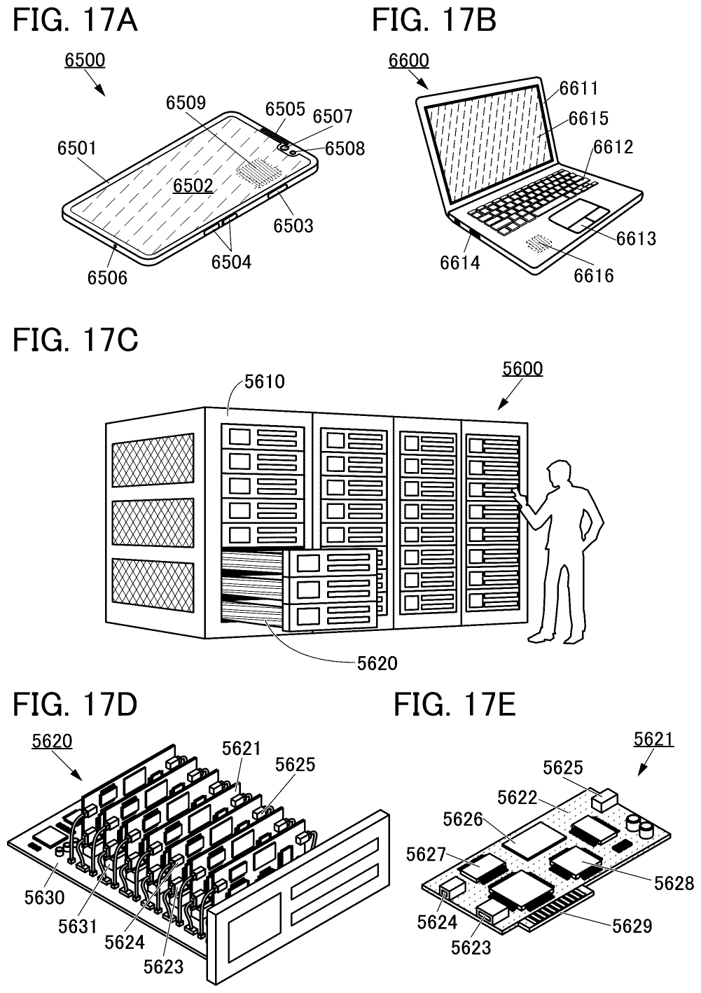

Next, FIG. 17A is a perspective view of an electronic device 6500. The electronic device 6500 in FIG. 17A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and storage device are included. The semiconductor device of one embodiment of the present invention can be used for the display portion 6502, the control device 6509, and the like.

An electronic device 6600 illustrated in FIG. 17B is an information terminal that can be used as a laptop personal computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a storage device are included. The semiconductor device of one embodiment of the present invention can be used for the display portion 6611, the control device 6616, and the like. Note that the semiconductor device of one embodiment of the present invention is preferably used for the control device 6509 and the control device 6616, in which case power consumption can be reduced.

### [Large Computer]

Next, FIG. 17C is a perspective view of a large computer 5600. In the large computer 5600 illustrated in FIG. 17C, a plurality of rack mount computers 5620 are stored in a rack 5610. Note that the large computer 5600 may be referred to as a supercomputer.

The computer 5620 can have a structure in a perspective view illustrated in FIG. 17D, for example. In FIG. 17D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 17E is an example of a processing board provided with a CPU, a GPU, a storage device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 17E also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device or the like. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space, such as devices processing and storing information.

The semiconductor device of one embodiment of the present invention can include an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

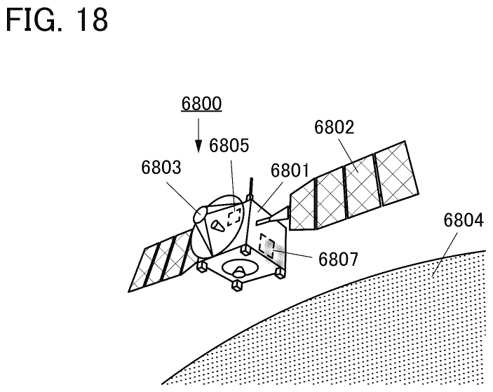

FIG. 18 illustrates an artificial satellite 6800 as an example of a device for space. The artificial satellite 6800 includes a body 6801, a solar panel 6802, an antenna 6803, a secondary battery 6805, and a control device 6807. In FIG. 18, a planet 6804 in outer space is illustrated. Note that outer space refers to, for example, space at an altitude greater than or equal to 100 km, and outer space described in this specification may also include thermosphere, mesosphere, and stratosphere.

Although not illustrated in FIG. 18, a battery management system (also referred to as BMS) or a battery control circuit may be provided in the secondary battery 6805. The battery management system or the battery control circuit preferably uses the OS transistor, in which case power consumption is low and high reliability is achieved even in outer space.

The radiation dose in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs an increase in building size for, for example, setting a storage and a server for retaining a huge amount of data, ensuring stable power supply for retaining data, ensuring cooling equipment for retaining data.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, a peripheral circuit, and the module can be reduced. Furthermore, the use of the semiconductor device of one embodiment of the present invention can achieve a data center that operates stably even in a high temperature environment. Thus, the reliability of the data center can be increased.

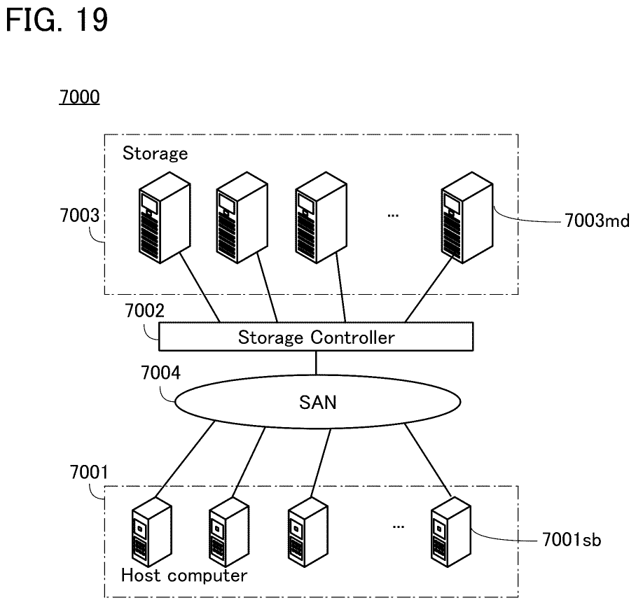

FIG. 19 illustrates a storage system that can be used in a data center. A storage system 7000 illustrated in FIG. 19 includes a plurality of servers 7001sb as host 7001 (indicated as “Host Computer” in the diagram). The storage system 7000 includes a plurality of storage devices 7003md as a storage 7003 (indicated as “Storage” in the diagram). In the diagram, the host 7001 and the storage 7003 are connected to each other through a storage area network 7004 (denoted by “SAN” in the diagram) and a storage control circuit 7002 (denoted by “Storage Controller” in the diagram).

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage. In the storage system, in order to solve the problem of low access speed of the storage 7003, a cache memory is normally provided in the storage to shorten the time for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on the data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

<Notes on Description of this Specification and the Like>

The following are notes on the description of the above embodiments and the structures in the embodiments.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, a content described in the embodiment is a content described using a variety of diagrams or a content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variations in signal, voltage, or current due to noise, variations in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or situation. For example, the term “conductive layer” can be changed into the term “conductive film” in some cases. For another example, the term “insulating film” can be changed into the term “insulating layer” in some cases.

In this specification and the like, a switch has a function of controlling whether current flows or not by being in a conduction state (on state) or a non-conduction state (off state). Alternatively, a switch has a function of selecting and switching a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### REFERENCE NUMERALS

10: semiconductor device, 20: base die, 21: power supply circuit, 30_1: die, 30_2: die, 30_3: die, 30: die, 31: power supply circuit, 32: functional circuit, 33: amplifier circuit, 34: transistor, 40: element layer, 41A: through electrode, 41B: through electrode, 41C: through electrode, 41D: through electrode, 42: metal bump, 47: electrode, 48: OS transistor, 49: Si transistor, 50: heat diffusion layer, 52: heat radiation layer

1. A semiconductor device comprising:
a base die comprising a first power supply circuit generating a first voltage;
a first die comprising a second power supply circuit generating a second voltage by being supplied with the first voltage; and
a second die comprising a functional circuit operating by being supplied with the second voltage,
wherein the first die and the second die each comprise a first through electrode and a second through electrode,
wherein the first die is provided over the base die,
wherein the second die is provided in contact with an upper layer or a lower layer of the first die,
wherein the base die and the first die are electrically connected via the first through electrode, and
wherein the first die and the second die are electrically connected via the second through electrode.

2. The semiconductor device according to claim 1, wherein the first power supply circuit is a switching regulator.

3. The semiconductor device according to claim 1, wherein the second power supply circuit is a series regulator.

4. The semiconductor device according to claim 1, wherein the functional circuit is a circuit configured to be an arithmetic circuit, a peripheral circuit, a memory circuit, and a driver circuit.

5. The semiconductor device according to claim 1, further comprising a heat radiation layer, wherein the heat radiation layer is provided between the first die and the second die.

6. The semiconductor device according to claim 1, wherein the first through electrode and the second through electrode provided in different dies are electrically connected via a metal bump.

7. The semiconductor device according to claim 1,
wherein the second die comprises a layer comprising a transistor in which a channel formation region comprises an oxide semiconductor, and
wherein the layer comprising the transistor is provided to be stacked.

8. The semiconductor device according to claim 7, wherein the oxide semiconductor comprises In, Ga, and Zn.

9. A semiconductor device comprising:
a base die comprising a first power supply circuit generating a first voltage;
a first die comprising a second power supply circuit generating a second voltage by being supplied with the first voltage; and
a second die and a third die each comprising a functional circuit operating by being supplied with the second voltage,
wherein the first die, the second die, and the third die each comprise a first through electrode and a second through electrode,
wherein the first die is provided over the base die,
wherein the second die is provided in contact with a lower layer of the first die,
wherein the third die is provided in contact with an upper layer of the first die,
wherein the base die and the first die are electrically connected via the first through electrode, and
wherein the first die, the second die, and the third die are electrically connected via the second through electrode.

10. The semiconductor device according to claim 9, wherein the first power supply circuit is a switching regulator.

11. The semiconductor device according to claim 9, wherein the second power supply circuit is a series regulator.

12. The semiconductor device according to claim 9, wherein the functional circuit is a circuit comprising one or more of functions of configured to be an arithmetic circuit, a peripheral circuit, a memory circuit, and a driver circuit.

13. The semiconductor device according to claim 9, further comprising a heat radiation layer, wherein the heat radiation layer is provided between the first die and the second die and between the first die and the third die.

14. The semiconductor device according to claim 9, wherein the first through electrode and the second through electrode provided in different dies are electrically connected via a metal bump.

15. The semiconductor device according to claim 9,
wherein the second die and the third die each comprise a layer comprising a transistor in which a channel formation region comprises an oxide semiconductor, and
wherein the layer comprising the transistor is provided to be stacked.

16. The semiconductor device according to claim 15, wherein the oxide semiconductor comprises In, Ga, and Zn.
